(19) United States
(12) Patent Application Publication
(10) Pub. No.: US 2025/0377264 A1
(43) Pub. Date: Dec. 11, 2025

(54) PARALLELIZED AND ASYNCHRONOUS EVALUATION TO OPTIMIZE FOR MAXIMAL EFFICIENCY OF INFORMATION GAIN

(71) Applicant: APPLIED INTUITION, INC., Mountain View, CA (US)

(72) Inventors: Yiqi HOU, San Ramon, CA (US); Justin DION, Campbell, CA (US); Alex GROH, Detroit, MI (US); Kenny HOANG, Mountain View, CA (US); Kimberli ZHONG, Dublin, CA (US)

(73) Assignee: APPLIED INTUITION, INC., Mountain View, CA (US)

(21) Appl. No.: 18/877,437

(22) PCT Filed: Jun. 21, 2023
(86) PCT No.: PCT/US2023/025906

§ 371 Date: Dec. 20, 2024

Related U.S. Application Data
(60) Provisional application No. 63/366,770, filed on Jun. 21, 2022.
(60) Provisional application No. 63/366,830, filed on Jun. 22, 2022.

(51) Int. Cl. G01M 17/007; G06F 30/15

(52) U.S. Cl. CPC G01M 17/007; G06F 30/15

(57) ABSTRACT

The disclosure relates to a device for vehicle testing that is configured to perform operations including testing a first test sample batch comprising a plurality of first test samples to output a plurality of first test sample results. identifying one or more asynchronous test sample results of the plurality of first test samples before the first test sample batch is complete. computing a parametric metric based on the one or more asynchronous test sample results. and adjusting a second test sample batch based on the parametric metric.

### RELATED APPLICATION

This application claims the benefit of U.S. Provisional Application No. 63/366,770, filed Jun. 21, 2022, and 63/366,830, filed Jun. 22, 2022, the disclosures of which are incorporated herein by reference in their entirety.

The present disclosure is related to vehicle simulation, testing, and validation systems and methods.

### BACKGROUND

Unless otherwise indicated herein, the materials described herein are not prior art to the claims in the present application and are not admitted to be prior art by inclusion in this section.

A simulated environment may be used to test software. For example, a simulated driving environment may be used to test software of an autonomous vehicle. An autonomous vehicle may use sensors to perceive its environment. Control systems may model sensory input from the sensors to determine a navigation path and make decisions in response to traffic controls such as stop lights, roundabouts, stop signs, speed limit changes, and other vehicles.

Vehicles may have various levels of automation. For some vehicles, an automated system may provide warnings but may not otherwise control the vehicle. For other vehicles, the vehicle may operate in many different surfaces, seasons, and weather conditions without human intervention. Consequently, devices, systems, and methods for testing, simulating, and validating vehicles having a wide range of automation levels may be useful.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

A device for vehicle simulation, testing, and validation may include a memory and a processor operatively coupled to the memory. The processor may be configured to identify a first parameter set defined using a first scenario format, where the first parameter set includes one or more first scenario format axes, one or more first scenario format relationships, and one or more first scenario format constraints. The processor may be configured to map the first parameter set to an internal parameter set using an internal parameter format, where the internal parameter format includes one or more internal axes, one or more internal relationships, and one or more internal constraints. The processor may be configured to generate a test configuration object using the internal parameter set, where the test configuration object is configured to link to one or more objects. The processor may be configured to send the test configuration object to a testing modality for testing.

A device for vehicle simulation, testing, and validation may include a memory and a processor operatively coupled to the memory. The processor may be configured to identify a first parameter set defined using a first scenario format, where the first parameter set includes one or more first scenario format axes, one or more first scenario format relationships, and one or more first scenario format constraints. The processor may be configured to map the first parameter set to an internal parameter set, where the internal parameter set includes one or more internal axes, one or more internal relationships, and one or more internal constraints. The processor may be configured to compute a parametric metric, where the parametric metric is based on one or more of a parametric performance metric or a parametric coverage metric.

A non-transitory computer-readable storage medium including computer executable instructions that, when executed by one or more processors, may cause a vehicle simulator to: receive scenario format data; convert the scenario format data into internal parameter format data; generate a test configuration object using the internal parameter format data; and test the test configuration object using a testing modality.

A device for vehicle simulation, testing, and validation may include a memory and a processor operatively coupled to the memory. The processor may be configured to test a first test sample batch that includes one or more first test samples to output one or more first test sample results. The processor may be configured to identify one or more asynchronous test sample results of the plurality of first test samples before the first test sample batch is complete. The processor may be configured to compute a parametric metric based on the one or more asynchronous test sample results, where the parametric metric includes one or more of a parametric performance metric or a parametric coverage metric. The processor may be configured to adjust a second test sample batch based on the parametric metric.

A device for vehicle simulation, testing, and validation may include a memory and a processor operatively coupled to the memory. The processor may be configured to identify one or more asynchronous test sample results of one or more first test samples before a first test sample batch has completed testing. The processor may be configured to compute a parametric metric, where the parametric metric is based on one or more of a parametric performance metric or a parametric coverage metric. The processor may be configured to select a set of algorithms based on the parametric metric. The processor may be configured to apply an algorithm of the set of algorithms to a second test sample batch before the first test sample batch has completed testing.

A computer-readable storage medium including computer executable instructions that, when executed by one or more processors, may cause a vehicle tester to: test a first test sample batch in a testing modality format, where the first sample batch includes one or more first test samples to output one or more first test sample results; identify one or more asynchronous test sample results of the plurality of first test samples before the first test sample batch is complete; convert the one or more asynchronous test sample results to an internal parameter format from the testing modality format; and adjust a second test sample batch based on the one or more asynchronous test sample results.

A device for vehicle simulation, testing, and validation may include a memory and a processor operatively coupled to the memory. The processor may be configured to compute an internal parameter set that includes one or more internal axes, one or more internal relationships, and one or more internal constraints. The processor may be configured to compute a metric using the internal parameter set, where the metric includes one or more of a performance metric or a coverage metric.

A device for vehicle simulation, testing, and validation may include a memory and a processor operatively coupled to the memory. The processor may be configured to identify a first parameter set defined using a first scenario format, where the first parameter set includes one or more first scenario format axes, one or more first scenario format relationships, and one or more first scenario format constraints. The processor may be configured to map the first parameter set to an internal parameter set, where the internal parameter set includes one or more internal axes, one or more internal relationships, and one or more internal constraints. The processor may be configured to compute a metric, where the metric is based on one or more of a performance metric or a coverage metric.

A device for vehicle simulation, testing, and validation may include a memory and a processor operatively coupled to the memory. The processor may be configured to test a first test sample batch that includes one or more first test samples to output one or more first test sample results. The processor may be configured to identify one or more asynchronous test sample results of the plurality of first test samples before the first test sample batch is complete. The processor may be configured to compute a metric based on the one or more asynchronous test sample results, where the metric includes one or more of a performance metric or a coverage metric. The processor may be configured to adjust a second test sample batch based on the metric.

A device for vehicle simulation, testing, and validation may include a memory and a processor operatively coupled to the memory. The processor may be configured to identify first test data based on a first testing modality, where the first test data includes one or more of first coverage test data, first performance test data, first metric distribution test data, or first uncertainty test data. The processor may be configured to compute a transformation function configured to transform the first test data from the first testing modality to a second testing modality, where the second testing modality is different than the first testing modality. The processor may be configured to compute, using the transformation function, second test data based on the first test data, where the second test data includes one or more of second coverage test data, second performance test data, second metric distribution test data, or second uncertainty test data.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

Example will be described and explained with additional specificity and detail through the use of the accompanying drawings in which:

FIG. 1A illustrates an example block diagram for vehicle simulation, testing, and validation.

FIG. 1B illustrates an example block diagram for vehicle simulation, testing, and validation.

FIG. 2 illustrates an example process flow for an internal parameter format in vehicle simulation, testing, and validation.

FIG. 3A illustrates an example process flow for parallelization in vehicle simulation, testing, and validation.

FIG. 3B illustrates an example process flow for parallelization in vehicle simulation, testing, and validation.

FIG. 4A illustrates an example process flow for metrics in vehicle simulation, testing, and validation.

FIG. 4B illustrates an example process flow for data indexing in vehicle simulation, testing, and validation.

FIG. 4C illustrates an example process flow for featurization in vehicle simulation, testing, and validation.

FIG. 4D illustrates an example process flow for data point probability distributions in vehicle simulation, testing, and validation.

FIG. 5 illustrates an example process flow for data probability distributions in vehicle simulation, testing, and validation.

FIG. 6 illustrates an example process flow for learning correlation in vehicle simulation, testing, and validation.

FIG. 7 illustrates an example process flow for an internal parameter format in vehicle simulation, testing, and validation.

FIG. 8 illustrates an example process flow for an internal parameter format in vehicle simulation, testing, and validation.

FIG. 9 illustrates an example process flow for an internal parameter format in vehicle simulation, testing, and validation.

FIG. 10 illustrates an example process flow for asynchronous information in vehicle simulation, testing, and validation.

FIG. 11 illustrates an example process flow for asynchronous information in vehicle simulation, testing, and validation.

FIG. 12 illustrates an example process flow for asynchronous information in vehicle simulation, testing, and validation.

FIG. 13 illustrates an example process flow for metrics in vehicle simulation, testing, and validation.

FIG. 14 illustrates an example process flow for metrics in vehicle simulation, testing, and validation.

FIG. 15 illustrates an example process flow for metrics in vehicle simulation, testing, and validation.

FIG. 16 illustrates an example process flow for transformation functions in vehicle simulation, testing, and validation.

FIG. 17 illustrates a diagrammatic representation of a machine in the example form of a computing device within which a set of instructions, for causing the machine to perform any one or more of the methods discussed herein, may be executed.

### DESCRIPTION OF EMBODIMENTS

A vehicle software testbed, which may be an autonomous-vehicle software testbed, may be used to test vehicle software (or autonomous vehicle software). The vehicle software testbed may simulate a driving environment to test the vehicle software (e.g., to determine how the vehicle software would perform in various driving situations). For example, the vehicle software testbed may simulate a three dimensional (3-D) geographical environment and provide inputs to the vehicle software that may be analogous to inputs that the vehicle software may receive in real-world driving conditions if the vehicle software were running on a vehicle navigating within the actual geographical environment.

Determining the set of scenarios to generate and run in simulation is useful for efficiently testing and validating vehicle systems, and more specifically autonomous vehicle (AV) systems. Identifying a set of scenarios to sufficiently cover the testing space to a statistical degree of confidence helps demonstrate the accuracy and safety of the underlying system under test.

Prior approaches to scenario generation and coverage calculations have been based on three underlying assumptions: (1) A scenario definition language optimized for easy (but not necessarily comprehensive) parameterization; (2) Contextualization and introspection into the simulation environment and stack; and (3) access to a closed-loop testing environment. From these three assumptions, validation engineers may define the parameters that make up their tests, failure conditions for the test, and the range and step sizes of each parameter's possible values. Combinations of parameters are then iteratively tested, and new combinations are selected to gather additional information about the stack. Calculation of coverage is then based on what parameter values were tested across the set of tests. Coverage is computed naively by binning parameters into multi-dimensional histograms and clusters.

A limitation of these prior approaches is their reliance on the details of each of the three assumptions above. In particular, much prior work is dependent on specialized scenario definition formats, which may limit the expressiveness and extensibility of many aspects of the scenario as compared to using an industry standard scenario language. Additionally, these scenario languages are often closely tied to the ability to introspect and modify these scenarios. And, the closed-loop simulation environments for their execution may not be realistic enough to provide accurate and realistic prior information to adaptively sample. On top of this, many of these algorithms fully rely on a prior sample to have been collected before selecting the next sample to run. Thus, the ability of prior approaches to scale has been limited, resulting in these approaches being primarily limited to research contexts. Finally, the naive approach to computing coverage results in a limited ability to evaluate the performance and test coverage of a stack relative to how important different scenarios are.

Aspects of the present disclosure provide systems and methods for enhanced simulations, scenario selection, and environment generation, among other aspects. For example, systems and methods provide enhanced efficiency, such as through information sharing between different testing modalities. The increased information sharing allows sampling to occur more logically and more efficiently.

Additional efficiency gains may arise from the evaluation of stacks (e.g., performance and coverage), which may otherwise be a manual process, while a statistical interface may expedite evaluation. Performance gains arising from parallelizable simulation and different testing modalities may generate sampling algorithms that may converge more quickly. And, with the disclosed techniques, AV testing may identify failure modes more quickly and may statistically validate autonomy stacks.

Other aspects may provide a set of meta-statistics that quantify the amount of information loss that occurs when transforming between the different testing modalities and risky/uncertain areas based on this transformation. A set of meta-statistics may quantify an amount of testing saved in each modality based on this correlation.

In yet a further aspect, the present disclosure includes methods for correlating information from software-in-the-loop (SIL), hardware-in-the-loop (HIL), and track testing to make predictions about performance in different situations. Aspects may provide a definition of a transformation function between SIL, HIL, and track testing performance, coverage, or metric distributions, and the corresponding uncertainty.

A device for vehicle simulation, testing, and validation may include a memory and a processor operatively coupled to the memory. The processor may be configured to identify a first parameter set defined using a first scenario format, where the first parameter set includes one or more first scenario format axes, one or more first scenario format relationships, and one or more first scenario format constraints. The processor may be configured to map the first parameter set to an internal parameter set using an internal parameter format, where the internal parameter format includes one or more internal axes, one or more internal relationships, and one or more internal constraints. The processor may be configured to generate a test configuration object using the internal parameter set, where the test configuration object is configured to link to one or more objects. The processor may be configured to send the test configuration object to a testing modality for testing.

A device for vehicle simulation, testing, and validation may include a memory and a processor operatively coupled to the memory. The processor may be configured to test a first test sample batch that includes one or more first test samples to output one or more first test sample results. The processor may be configured to identify one or more asynchronous test sample results of the plurality of first test samples before the first test sample batch is complete. The processor may be configured to compute a parametric metric based on the one or more asynchronous test sample results, where the parametric metric includes one or more of a parametric performance metric or a parametric coverage metric. The processor may be configured to adjust a second test sample batch based on the parametric metric.

A device for vehicle simulation, testing, and validation may include a memory and a processor operatively coupled to the memory. The processor may be configured to compute an internal parameter set that includes one or more internal axes, one or more internal relationships, and one or more internal constraints. The processor may be configured to compute a metric using the internal parameter set, where the metric includes one or more of a performance metric or a coverage metric.

A device for vehicle simulation, testing, and validation may include a memory and a processor operatively coupled to the memory. The processor may be configured to identify first test data based on a first testing modality, where the first test data includes one or more of first coverage test data, first performance test data, first metric distribution test data, or first uncertainty test data. The processor may be configured to compute a transformation function configured to transform the first test data from the first testing modality to a second testing modality, where the second testing modality is different than the first testing modality. The processor may be configured to compute, using the transformation function, second test data based on the first test data, where the second test data includes one or more of second coverage test data, second performance test data, second metric distribution test data, or second uncertainty test data.

Embodiments of the present disclosure will be explained with reference to the accompanying drawings.

A scenario-agnostic internal representation of parameter spaces may be used to map between open and/or custom representations to internal representations. The parameter space itself may be operated on to reduce the complexity and difficulty of the problem for search/optimization algorithms. Some example data representations may include scenario definition language (Association for Standardization of Automation and Measuring Systems (ASAM) Open Scenario® (OSC) 1.0, OSC 2.0, or any other scenario language), axes (variables and their possible values, as well as output test metrics), relationships (define how variables relate to each other), constraints (define bounds of axes and limitations in relationships), or the like.

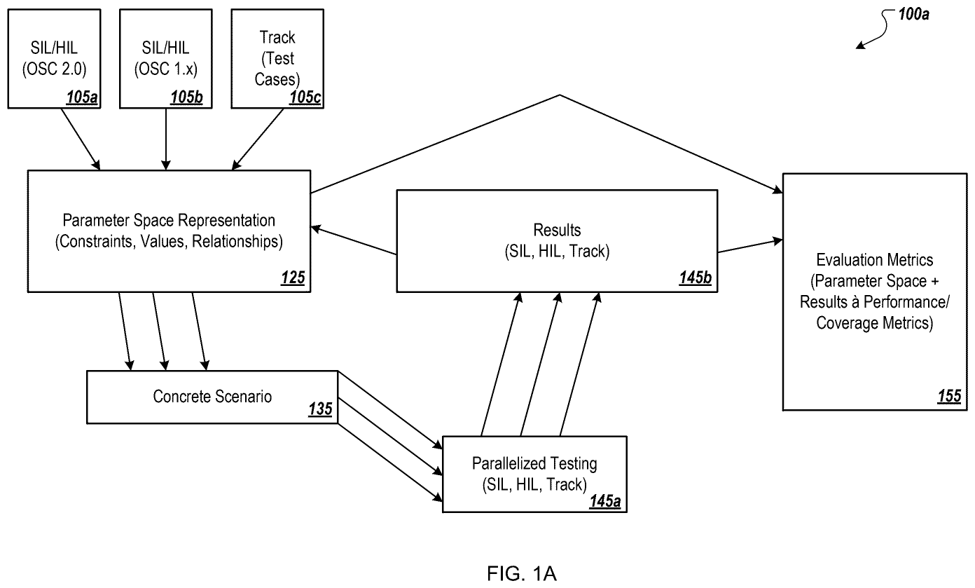

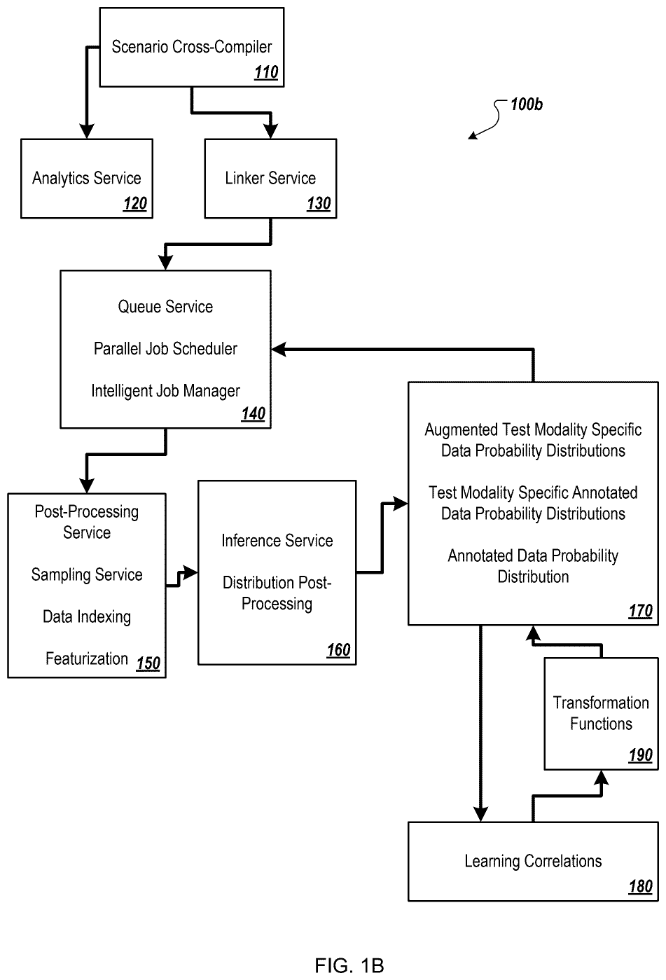

As illustrated in FIG. 1A, a block diagram 100a for vehicle testing, simulation, and validation is provided. A set of parameters may be defined including a mapping from any scenario language (e.g., an open scenario format such as OSC) or a proprietary scenario format such as a test specification for an HIL rig) to an internal parameter format. That is, various scenario definition languages including SIL/HIL provided in OSC 2.0 as shown in block 105a, SIL/HIL, OSC 1.x, as shown in block 105b, or track (test cases), as shown in block 105c may be mapped to a parameter space representation that includes one or more constraints, one or more values, or one or more relationships, as shown in block 125.

Parallelized and/or asynchronous evaluation may provide maximal efficiency of information gain. The parallelized simulations may allow for large-scale gathering of information and generation of subsequent samples. Asynchronous evaluation may allow for collection from hardware-in-the-loop (HIL)/on-vehicle testing results to continue to inform testing. In some aspects, the techniques may include methods for using asynchronous information to make decisions about further optimizations.

Therefore, the simulations may be executed in a parallelized way. The system may utilize parallelized assumptions to enable asynchronous updating of a prior for the sampling algorithm and parameter space. In particular, the system may have the ability to enqueue a new scenario and may build an updated prior based on all of the data gathered so far, and use that prior to enqueue the next scenario. Additionally, the unified parameter space representation allows the system to asynchronously update this parameter space performance using real world data as well.

The parameter space representation, as shown in block 125, may be used to generate a concrete scenario, as shown in block 135. The concrete scenario may be input to a parallelized testing operation that includes various testing modalities (e.g., SIL, HIL, track), as shown in block 145a. The results (e.g., SIL, HIL, track) from the parallelized testing may be collected for different testing modalities, as shown in block 145b. The results shown in block 145b may be fed back to the parameter space representation, as shown in block 125, to continue the process of generating further concrete scenarios, further parallelized testing, and so forth.

Various metrics may be used for evaluating coverage and performance over scenario spaces. These scenarios may also allow for querying and auditing of safety in a quantifiable way. And, these aspects may enable the sampling algorithms to optimize parallelization in a way that maximizes the statistical information metrics. Furthermore, a single high-level statistically meaningful metric may be used to describe performance and coverage. The metrics may include (a) an estimate of performance, with a confidence level and confidence interval, in which the unified parameter space may be normalized, and (b) an estimate of coverage based on sample density, in which the unified parameter space may be normalized, and (c) a unified metric with respect to the unified parameter space and a set of objective functions (e.g., Boolean or continuous) and real-world observations.

Thus, the results shown in block 145b may be input to an evaluation metrics operation, as shown in block 155. The evaluation metrics operation may be configured to convert the test results using a parameter space representation to generate performance/coverage metrics as described.

Information may be correlated from SIL, HIL, and track testing to make inferences about performance in different situations. A transformation function may be determined between SIL, HIL, and track testing performance, coverage, or metric distributions, and the corresponding uncertainty. A set of meta-statistics may quantify an amount of information loss when transforming between the different testing modalities and risky/uncertain areas based on this transformation. A set of meta-statistics may quantify an amount of testing saved in each modality based on this correlation.

An example process flow 100b for vehicle simulation, testing, and validation is provided in FIG. 1B. The scenario cross-compiler 110 may be configured to map from a scenario language (e.g., an open scenario format such as OSC or a proprietary scenario format such as a test specification for an HIL rig) to an internal parameter format (e.g., an intermediate YAML format). The internal parameter format may be provided to an sampling service 120, which may be configured to store and/or process one or more axes, one or more relationships, or one or more constraints computed using the internal parameter format. The linker service 130 may use the internal parameter format to create a test configuration object that may link between different objects, test results, or the like.

The linker service 130 may be configured to provide the test configuration object to a block 140 that includes one or more of a queue service, a parallel job scheduler, or an intelligent job manager. The queue service may submit the test configuration object to a plugin or service based on the satisfaction of specific constraints. The parallel job scheduler may schedule jobs for different testing modalities, simulators, or the like. The intelligent job manager may determine different jobs to test based on sampling of a probability distribution.

The test results arising from the combined operations of the queue service, parallel job schedule, and intelligent job manager may be provided to a block 150 that includes a post-processing service, a sampling service, data indexing, and featurization. The post-processing service may spin down the software. The sampling service, data indexing, and featurization may group primary indexes with filtered values based on feature vectors. The data from block 150 may be provided to block 160 that includes an inference service and distribution post-processing. The inference service may filter the relevant test agnostic data into a multi-dimensional distribution. Distribution post-processing may generate an annotated data point probability distribution using a data point probability distribution.

The annotated data point probability distribution may be provided to block 170, which may comprise various other probability distributions (augmented test modality specific data point probability distributions, test modality specific annotated data probability distributions). The probability distributions from block 170 may be provided to a learning correlation block 180, which may be configured to generate a transformation function 190. The transformation function 190 may be configured to transform between different testing modalities or other distributions. The augmented test modality specific data point probability distributions may be provided to block 140 to continue the testing process.

### Internal Representation

A variety of industry-standard scenario formats or custom formats may be used in the simulation, testing, and validation of vehicles, such as autonomous vehicles. A scenario-agnostic internal representation of parameter spaces (e.g., an internal parameter format) and mappings between open standards to this internal representation (e.g., an internal parameter format) may allow for a mapping between a variety of industry-standard scenario formats or custom formats to this internal representation (e.g., internal parameter format). An internal representation of parameter spaces (e.g., an internal parameter format) may allow for inclusion of information across one or more testing modalities to facilitate additional information about the coverage and performance of parameter spaces.

An internal representation of parameter spaces (e.g., an internal parameter format) may comprise one or more components including: (i) one or more axes that may comprise one or more variables and the possible values for the one or more variables, (ii) one or more relationships that may include one or more relationships between the one or more variables for the one or more axes, and one or more combinations between the one or more variables for the one or more axes, and (iii) one or more constraints that may: define the one or more bounds of a variable in relation to the other variables of the one or more variables, and define other regions in the scenario space that may be invalid.

With this internal representation of parameter spaces (e.g., an internal parameter format), a wide variety of statistical operations may be performed in a scenario and testing modality agnostic way. In particular, various statistical operations such as multi-dimensional clustering, nearest-neighbor analysis, parametric (or non-parametric) and/or linear (or nonlinear) regressions, or the like may be performed to inform sampling algorithms more effectively compared to a baseline sampling algorithm in which the various statistical operations are not used. In particular, various statistical operations may be used to mutate an abstracted parameter space in an invertible way such that optimization and search algorithms may operate on a search space more efficiently (e.g., with respect to computational complexity) compared to a parameter space in which the various statistical operations have not been performed. In particular, the application of these statistical operations may facilitate (when compared to a parameter space in which the various statistical operations have not been performed) one or more of: (a) dimensionality reduction, (b) conversion from non-convex to convex search spaces, or (c) increasing the connectivity and/or continuity of the scenario space.

An internal representation of parameter spaces (e.g., an internal parameter format) may be used in a device operable for one or more of vehicle simulation, vehicle testing, or vehicle validation. The device may comprise a memory and a processor operatively coupled to the memory. The processor may be configured to execute instructions to cause the device to identify a first parameter set defined using a first scenario format. The first parameter set may comprise one or more of: (i) one or more first scenario format axes; (ii) one or more first scenario format relationships; or (iii) one or more first scenario format constraints. The processor may be configured to execute instructions to cause the device to map the first parameter set to an internal parameter set using an internal parameter format, where the internal parameter format includes one or more of: (i) one or more internal axes, (ii) one or more internal relationships, or (iii) one or more internal constraints. The processor may be configured to execute instructions to cause the device to generate a test configuration object using the internal parameter set. The test configuration object may be configured to link to one or more objects. The processor may be configured to execute instructions to cause the device to send the test configuration object to a testing modality for testing.

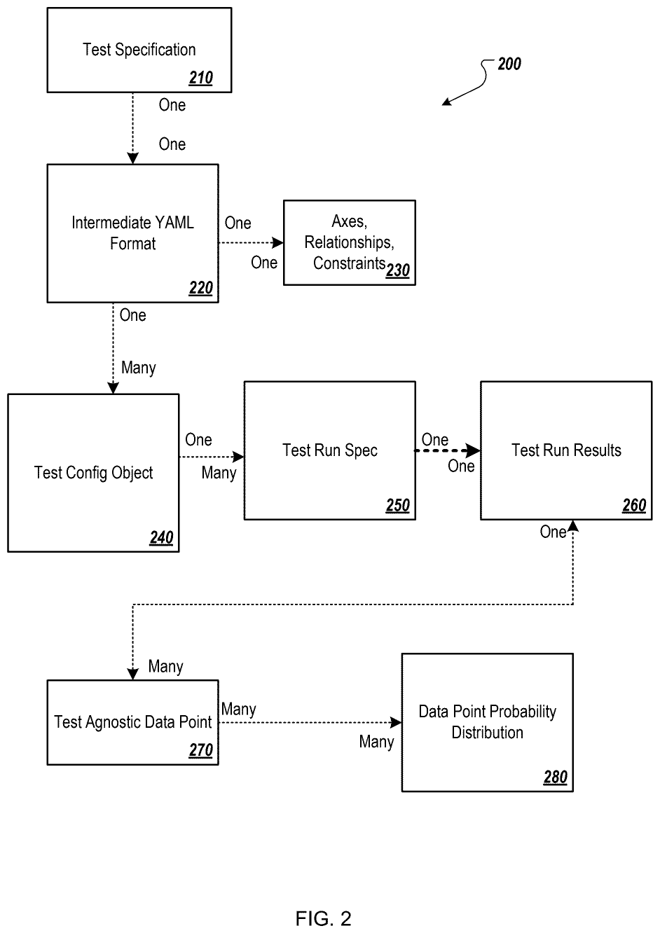

A process flow 200 for vehicle simulation, testing, or validation may be provided as illustrated in FIG. 2. An input (e.g., a test specification 210) relating to a scenario in a first scenario format (e.g., a scenario definition language) may be identified. The test specification 210 may comprise one or more of: a hardware in the loop (HIL) test specification, a software in the loop (SIL) test specification, or a field test specification. An HIL test specification may comprise, e.g., a dSpace® HIL specification. An SIL test specification may be implemented using a first scenario format (e.g., a scenario definition language) such as OSC 1.0, OSC 2.0, a different scenario language, or the like.

In one example, when scenarios are outside of a particular scenario language, the scenarios may be imported or converted into a particular scenario language. When in a particular scenario language, the test specification 210 may be cross-compiled into an internal parameter format, which may be an intermediate Yet Another Markup Language (YAML) format, as shown in operation 220, which may occur in a one-to-one operation. The internal parameter format may comprise one or more of: (i) one or more internal axes, (ii) one or more internal relationships, (iii) one or more internal constraints, (iv) one or more internal metrics, or (v) one or more parsing operation information facilitating conversion back into the first scenario format (e.g., a particular scenario language).

In another example, when scenarios are in a particular scenario language, the internal parameter format may be configured for conversion from the particular scenario language into the internal parameter format without importing or converting the scenario into a particular scenario language. The internal parameter format may comprise additional conversion data that may be used to facilitate the conversion from the particular scenario language into the internal parameter format.

Consequently, cross-compiling the test specification 210 into a first parameter set in the internal parameter format may cause the one or more internal axes, one or more internal relationships, or the one or more internal constraints to be parsed into the internal parameter format, as shown in operation 230, which may occur in a one-to-one operation. The internal parameter format (e.g., a YAML format test specification) may be interchangeable between various testing modalities (e.g., HIL, SIL, field test, or the like) and simulators (e.g., HIL simulators, SIL simulators, field test simulators, or the like). This internal parameter format may comprise one or more parsing operation information (e.g., relevant links and contextual information) that may be used to identify a compilation source in the internal parameter format to facilitate tracing the internal parameter set in the internal parameter format back to a first parameter set in a first parameter format (e.g., a particular scenario language to identify information that may be specific to the particular scenario language). The internal parameter format may comprise one or more internal metrics for generating metrics using axes when results are available after testing.

The first parameter set in the internal parameter format may be used to generate one or more of a test configuration object, a test run specification, or a test run result. The first parameter set in the internal parameter format, e.g., an intermediate YAML format, may be used to generate a test configuration object (i.e., a test config object), as shown in operation 240, which may be a one to many operation. The test configuration object may comprise references to one or more of test specifications, parameter sets in the internal parameter formats, test results, or the like to facilitate indexing data relating to a particular test.

To initiate testing, a request that includes the first parameter set in the internal parameter format (and related links) may be sent to a micro-service to enqueue testing jobs to generate a test run specification, as shown in operation 250, which may be a one-to-many operation. The test run specification may be a data package that includes the information used to execute a test in a testing environment. This information that may be used to execute a test in a testing environment may include one or more of: (i) a test environment specification, (ii) references to one or more input files such as test specification files, (iii) runtime parameters, or the like. The test configuration object may be formatted into a testing modality format (e.g., a format specific for SIL, HIL, track, or the like) for the testing modality (e.g., SIL, HIL, track, or the like). The formatted test configuration object may be sent to a testing modality (e.g., a SIL test, a HIL test, a track test, or the like) associated with the testing modality (e.g., SIL, HIL, track, or the like).

The request to generate the test run specification, based on the requested testing modality, may be forwarded to one or more interfaces to one or more testing modalities including: (i) an interface to a particular test scenario simulator, (ii) a plugin interface to one or more of an external SIL simulator or an external HIL simulator, or (iii) a plugin interface to an automated track testing job queue. These one or more interfaces may perform further formatting from the internal parameter format (e.g., intermediate scenario language) into the test specification. The further formatting may include one or more of: HIL rig specifications, track testing specifications, SIL specifications, or the like. These interfaces (e.g., plugin interfaces) may submit the request to a corresponding testing modality (e.g., a SIL testing modality for a SIL test specification, a HIL testing modality for a HIL test specification, a tracking testing modality for a track testing specification, or the like) via available web application protocol interfaces (APIs) (e.g., representational state transfer (REST), hypertext transfer protocol (HTTP), or the like).

As shown in operation 260, the test run specification operation 250 may generate test run results which may be a one to one operation. The test run results may include one or more of: drive data, simulation data, or additional data that may be parsed based on an axis type.

Test modality format data may be converted, at an internal parameter format converter plugin, into internal parameter format data. In one example, external test run results (e.g., test run results for a particular scenario language) may be received using a converter plugin. The external test run results may comprise various testing modalities including one or more of SIL, HIL, drive, or the like. The converter plugin may receive various inputs including: (i) an internal parameter format, (ii) a drive log of arbitrary format, or the like. The converter plugin may define a conversion from the drive log format to the internal parameter format. A metric in the internal parameter format may be identified after testing.

The test run results may be used to generate test agnostic data points, as shown in operation 270, using a one-to-many operation. The test run results, which may include drive data, simulation data, or the like, may be present in a time-based metrics format. The time-based metrics format may be collected from various testing modalities such as SIL, HIL, drive, track, or the like. The time-based metrics format may be converted into the internal parameter format (e.g., the intermediate YAML format). The time-based metrics format may be converted into the internal parameter format based on one or more of: (i) one or more internal axes, (ii) one or more internal relationships, or (iii) one or more internal constraints.

An internal parameter format converter plugin may be configured to convert axes data in a time-based metrics signal format into internal parameter format data, and write the axes data to a database. In one example, the time-based metrics format may be converted into an intermediate YAML format using a YAML template for the axes to generate intermediate YAML format metrics. A post-processing micro-service may compute relevant axes values from these intermediate YAML format metrics, which may be written to a database. Any axes that violate the constraints or relationships as specified in the intermediate YAML format may be updated in the intermediate YAML format to include input axes values that may be identified as not being tested.

The test agnostic data points, which may be generated as shown in operation 270, may be used to generate a data point probability distribution, as shown in operation 280, which may be a many-to-many operation. The data point probability distribution may be generated using one or more of: (i) axes referenced in the particular data point probability distribution, (ii) values referenced in the particular data point probability distribution, or (iii) parameters referenced in the particular data point probability distribution.

The scenario definition language may comprise various scenario languages (e.g., an open scenario format such as OSC or a proprietary scenario format such as a test specification for an HIL rig). In one example, the scenario definition language may be an open scenario language. When an open scenario language is used, a simulator (e.g., an automated vehicle (AV) simulator) may be configured to receive scenario format data and convert the scenario format data into internal parameter format data (e.g., intermediate YAML format data as shown in operation 220). The vehicle simulator may be configured to generate a test configuration object using the internal parameter format data (e.g., as shown in operation 240), and test the test configuration object using a testing modality (e.g., as shown in operation 250). The vehicle simulator may be configured as otherwise disclosed with respect to generating an internal representation of parameter spaces provided herein.

The vehicle simulator may be configured to generate various metrics (e.g., as shown in operation 260) to measure one or more of the coverage or performance of the vehicle simulator. The vehicle simulator may be configured to compute a parametric metric (e.g., a metric that is computed in a parametric format). The parametric metric may be based on one or more of a parametric performance metric or a parametric coverage metric. The parametric metric may be selected based on a particular use case type. The vehicle simulator may be configured to retrieve one or more axes values for the testing modality, and compute one or more axes-specific metrics based on the one or more axes values. The vehicle simulator may be configured to generate the test configuration object based on one or more axes-specific metrics, where the one or more axes-specific metrics are based on one or more axes value selected based on the parametric metric.

### Parallel Simulations Using Asynchronous Information

Functionality for vehicle simulation, testing, or validation may be configured using asynchronous information to generate simulations in parallel. Combining asynchronous information and parallelized simulations may enhance information gain over a particular time for a selected amount of computational resources. Parallelized simulations may facilitate large-scale gathering of information and generation of subsequent samples. Asynchronous information updates may facilitate collection from various testing modalities (e.g., SIL, HIL, track) to determine subsequent testing. Testing that combines parallel job scheduling with asynchronous information may enhance the information gain when compared to the baseline approach because partial information may be used to update parallel testing that is currently executing without random scheduling of subsequent testing jobs and without waiting for complete information before adjusting subsequent testing jobs.

In addition, adding, adjusting, or terminating different test samples based on asynchronous information before the completion of testing for a particular test batch may reduce the computational complexity to achieve convergence for particular testing cases when compared to a baseline computational complexity in which: asynchronous information is not used, parallel testing is not used, or neither asynchronous information nor parallel testing is used. The reduction in computational complexity to achieve convergence for a particular testing case may occur because of the increased testing of one or more of highly-sensitive cases, under-determined cases, edge cases, or failure-prone cases when compared to the baseline computational complexity and the decreased testing of lower-information cases that may provide lower information when compared to a baseline testing case. For example, lower-information cases may include low-sensitivity cases, high-coverage cases, redundant testing cases, cases with adequate testing coverage, low-failure cases, or the like.

The operations on the sampling algorithm and the parameter space may be updated asynchronously using parallelized assumptions. That is, when a scenario is being enqueued, an updated prior may be generated based on the collected data to enqueue subsequent scenarios. The scenario may include data that has been collected asynchronously using an internal parameter format. The asynchronously collected data may include one or more of simulated data or real-world data.

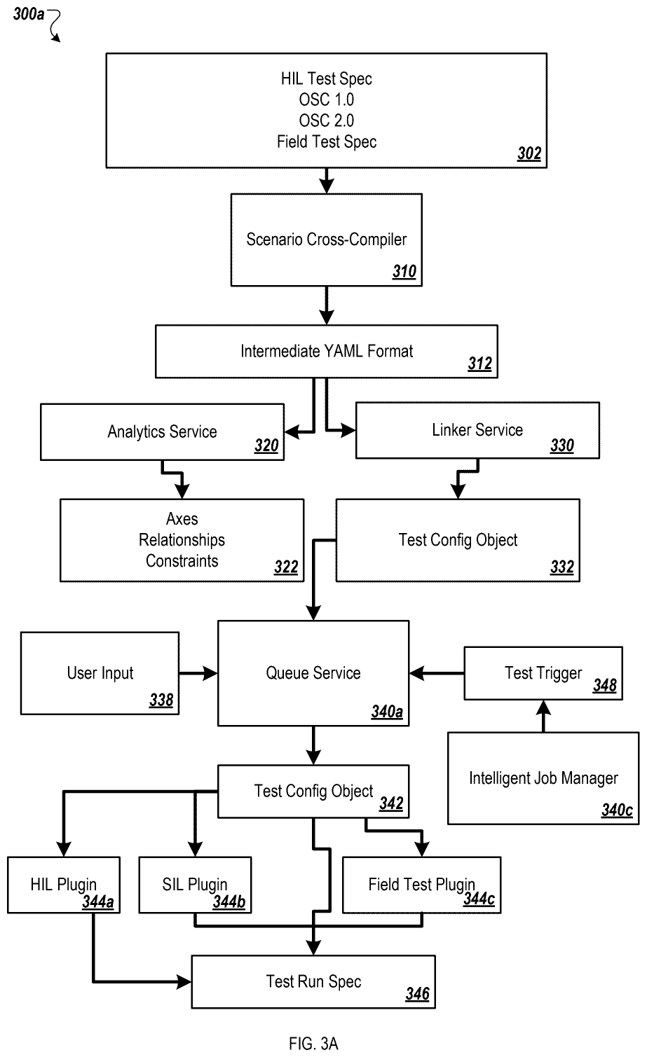

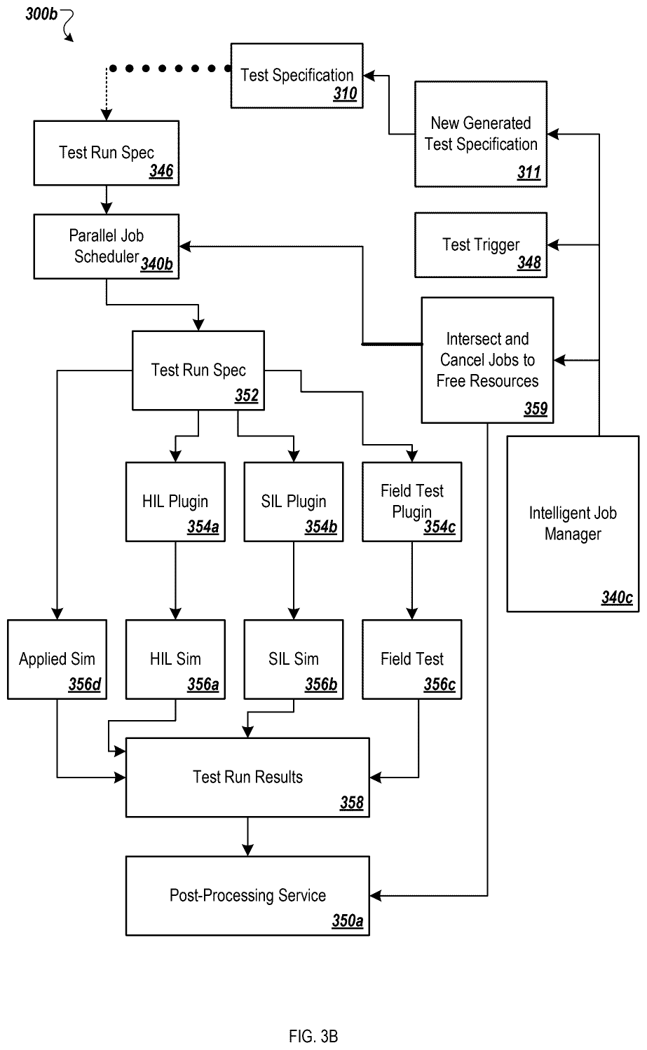

A vehicle simulator may be configured for one or more of simulation, testing, or validation as provided in the process flow 300a in FIG. 3A. The vehicle simulator may be configured to test a first test sample batch in a testing modality format. The first sample batch may comprise one or more first test samples to output one or more first test sample results. The vehicle simulator may be configured to identify one or more asynchronous test sample results of the plurality of first test samples before the first test sample batch is complete. The vehicle simulator may be configured to convert the one or more asynchronous test sample results to the internal parameter format from the testing modality format. The vehicle simulator may be configured to adjust a second test sample batch based on the one or more asynchronous test sample results.

The vehicle simulator may be configured to adjust one or more subsequent test sample batches based on one or more previous test sample batches until a metric (e.g., a convergence metric, a confidence metric, a coverage metric, a sampling metric, or the like) has been achieved. For example, after testing first and second batches, a coverage metric may not have achieved a selected threshold. In this example, the vehicle simulator may be configured to adjust subsequent test sample batches (e.g., third, fourth, and so forth) until the coverage metric has achieved the selected threshold. The testing of subsequent test sample batches may be iterated until the selected coverage metric has been achieved.

The vehicle simulator may be configured to process a test specification for sending to a queue service 340a using one or more operations. The test specification may include one or more of an HIL test specification, an OSC® 1.0 or OSC® 2.0 test specification, a field test specification, or the like, as shown in block 302. The test specification may be provided to a scenario cross compiler 310 which may compile the test specification into an internal parameter format (e.g., an intermediate YAML representation), as shown in block 312.

The internal parameter format (e.g., an intermediate YAML representation) may be provided to one or more of a sampling service 320 or a linker service 330. The sampling service 320 may generate an object representation of one or more of: one or more axes (e.g., numeric or discrete axes), one or more relationships, or one or more constraints, as shown in block 322. The linker service 330 may receive the internal parameter format (e.g., the YAML representation) and generate a test configuration object, as shown in block 332, which may provide linking between one or more objects, results, or the like. The test configuration object, as shown in block 332, may be provided to a queue service 340a.

The queue service 340a may receive the test configuration object, as shown in block 332, and user input (e.g., a user request), as shown in block 338. The queue service 340a may submit the test configuration object, as shown in block 332, and the user input, as shown in block 338, to one or more of a plugin or service for execution based on the satisfaction of one or more constraints. The test configuration object, as shown in block 342, may be provided to one or more of the HIL plugin 344a, the SIL plugin 344b, the field test plugin 344c, or the test run specification 346.

The queue service 340a may receive a test trigger 348 from an intelligent job manager 340c. The intelligent job manager 340c may be configured to sample data probability distributions (e.g., augmented data probability distributions) for one or more testing cases for a specific testing modality (e.g., SIL, HIL, track, or the like). The one or more testing cases may be one or more of: highly-sensitive cases, under-determined cases, edge cases, or failure-prone cases. Highly-sensitive cases may be testing cases based on variables that may affect the outcome to a greater extent when compared to a baseline testing case. A baseline testing case may be a testing case that may be based on one or more of an average test sample result, a median test sample result, or the like. Under-determined cases may be testing cases that do not include adequate test sample results to provide adequate information about coverage, performance, or any other suitable metric. Edge cases may be testing cases that test a boundary between one or more different testing cases. Failure-prone cases may be testing cases that are more likely to result in failure compared to a baseline testing case.

The intelligent job manager 340c may be configured to identify previous test sample results, currently-executing test samples (e.g., test jobs, simulations, or the like), and the overall probability space for different testing cases. The intelligent job manager 340c may receive test sample results that may alter the data probability distribution. The test sample results may comprise asynchronous test sample results. The intelligent job manager 340c may be configured to receive and/or identify asynchronous test sample results from a first test sample batch in a specified testing modality format before the first test sample batch has completed testing. The intelligent job manager 340c may be configured to convert the asynchronous test sample results to an internal parameter format when the asynchronous test sample results are in a testing modality format (e.g., SIL, HIL, track, or the like).

The intelligent job manager 340c may be configured to adjust a second test sample batch based on the one or more asynchronous test sample results. For example, the intelligent job manager 340c may be configured to cancel, based on the asynchronous test sample results that may alter the data probability distribution, currently-executing test samples in the first test sample batch to free up computational resources for other testing when specific test sample results associated with the currently-executing test samples are not to be used to alter the data probability distribution. The cancellation request may be sent from the intelligent job manager 340c to the parallel job scheduler 340b (as illustrated in the block diagram 300b in FIG. 3B).

The intelligent job manager 340c may be configured to down-weight currently-executing test samples when sampling the data probability distribution to maximize information gain and minimize redundant testing. The currently-executing test samples may not have test sample results that are included in the data probability distribution, but the currently-executing test samples may be previously enqueued. Therefore, to avoid double-counting of the currently-executing test samples, the data probability distribution may be adjusted (e.g., down-weighted) based on currently-executing test samples.

The vehicle simulator may be configured to process a test specification to generate test run results 358 using one or more operations, as illustrated in FIG. 3B. The test run specification 346 (as provided by one or more of the queue service 340a, the HIL plugin 344a, the SIL plugin 344b, or the field test plugin 344c) may be provided to a parallel job scheduler 340b.

The parallel job scheduler 340b may be configured to: (i) test one or more test sample batches in various testing modality formats, and (ii) send the test sample batches to various testing modalities. A test sample batch may comprise one or more test samples that may be computed to output one or more test sample results.

The parallel job scheduler 340b may be configured to identify various parameters related to job scheduling including one or more of: randomness, learning rate decay, predicted sample size, test batch configuration parameters (e.g., hyper parameters relating to the past, present, and predicted future test executions). The parallel job scheduler may be implemented using various algorithms which may include hyper parameters based on the algorithm's operational parameters.

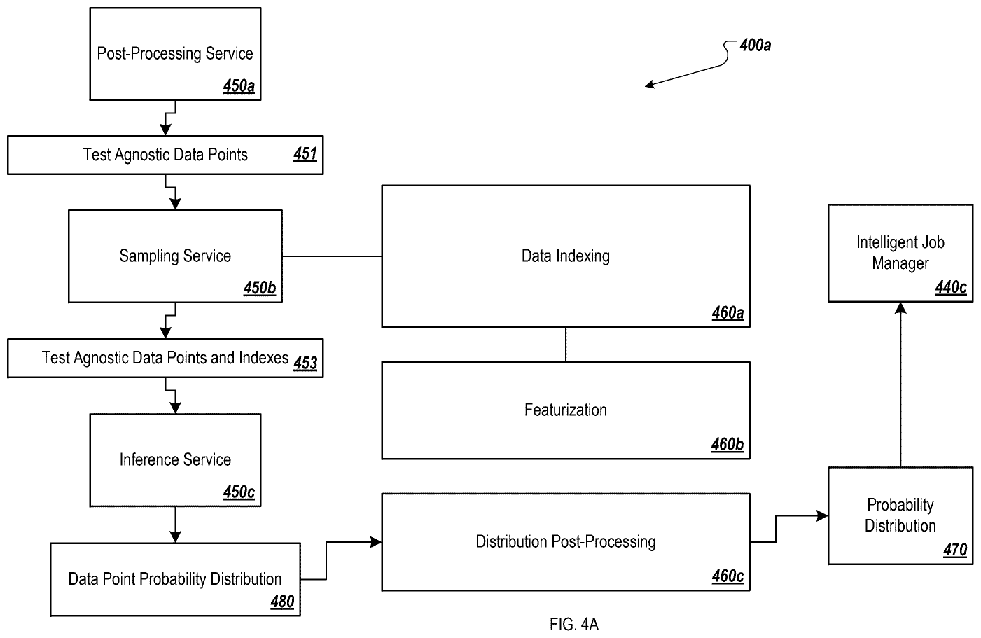

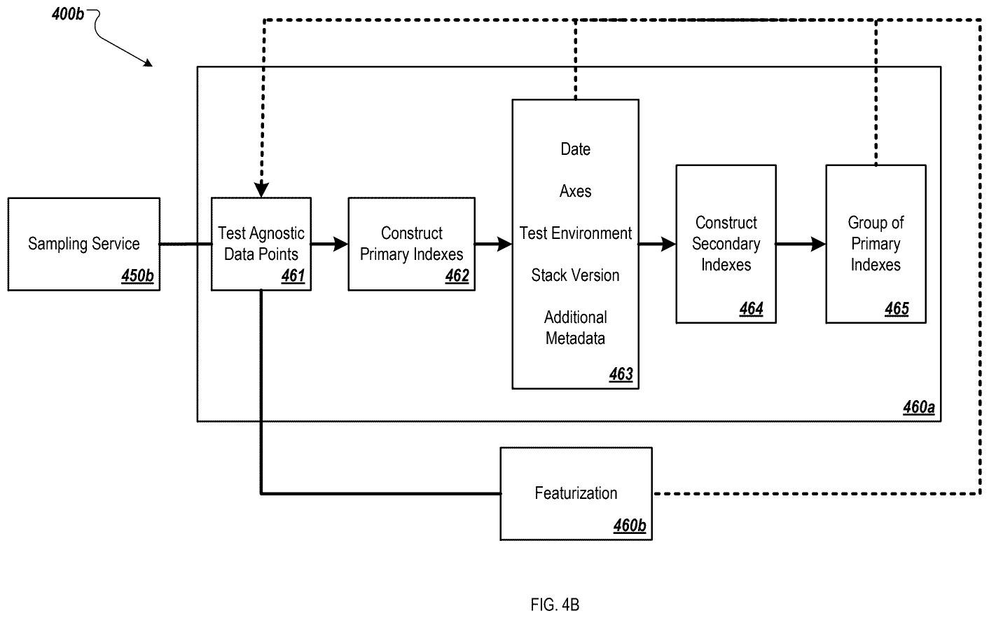

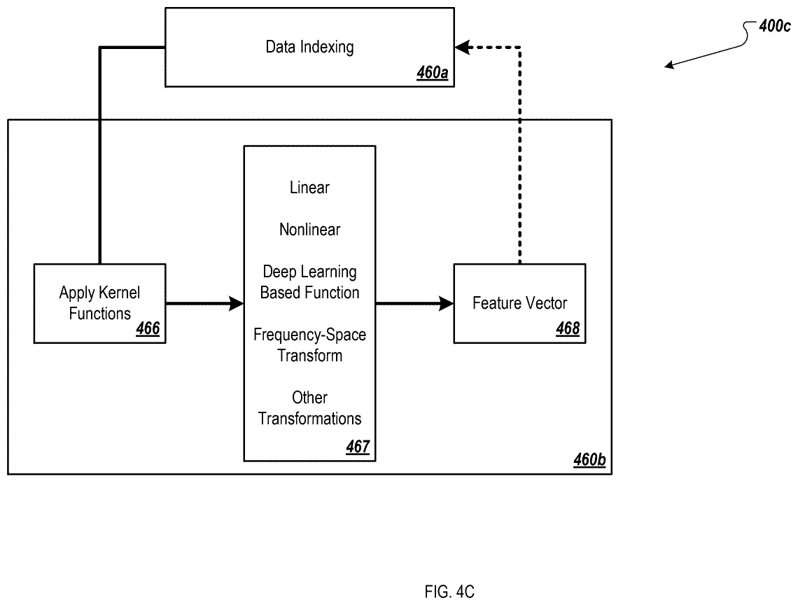

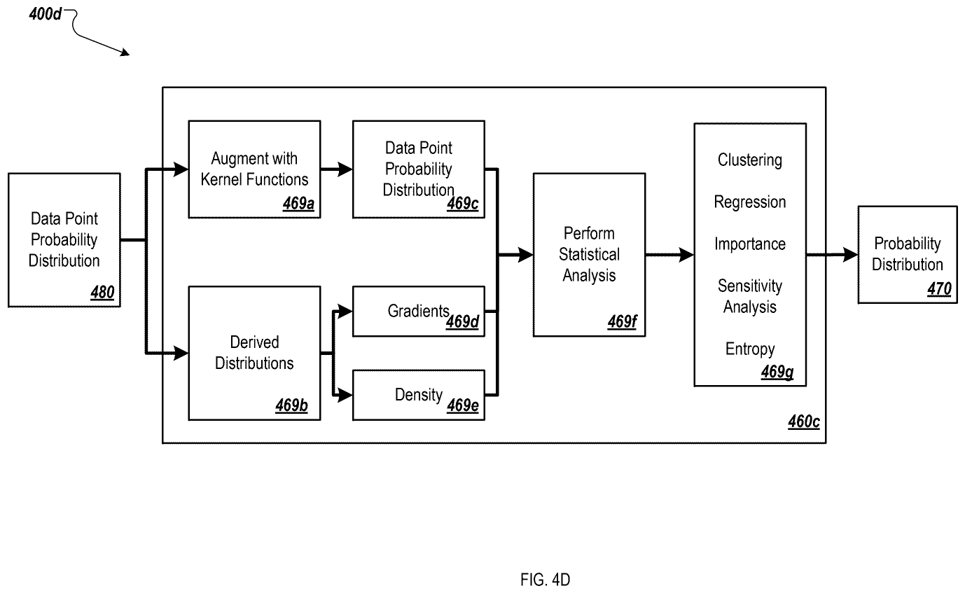

The parallel job scheduler 340b may be configured to select a test sample batch and provide that test sample batch in a test run specification 352 to one or more of: (i) one or more testing modality plugins (e.g., HIL plugin 354a, SIL plugin 354b, field test plugin 354c) for formatting into a testing modality format (e.g., HIL, SIL, field test, or the like) to be inputted to a testing modality (e.g., HIL simulation 356a, SIL simulation 356b, field test 356c), or (ii) or as input for a particular simulation 356d test. The results from one or more of the HIL simulation 356a, SIL simulation 356b, field test 356c, applied simulation 356d test or the like may be collected as test run results 358. These test run results may be provided to a job post-processing service 450a (as illustrated in FIG. 4A).

The parallel job scheduler 340b may be configured to schedule the one or more of the jobs, simulations, test batches, or the like to different testing modalities, simulators, or the like by allocating software, network, or other compute infrastructure to operate the different jobs, simulations, test batches, or the like in parallel. The intelligent job manager 340c may be configured to send, to the parallel job scheduler 340b, a request 359 to intersect and cancel jobs to free up computational resources. The intelligent job manager 340c may be configured to generate a test specification (e.g., new generated test specification 311) to be processed as a test specification by being input to the scenario cross compiler 310 (as shown in FIG. 3A).

The parallel job scheduler 340b may be configured to receive the request 359 to intersect and cancel jobs to free up computational resources. The request 359 to intersect and cancel jobs to free up computational resources may be based on asynchronous test sample results. Consequently, the parallel job scheduler 340b may adjust the subsequent test sample batches based on asynchronous test sample results. Alternatively, or in addition, the parallel job scheduler 340b may be configured to adjust one or more subsequent test sample batches based on one or more previous test sample batches until a metric (e.g., a convergence metric, a confidence metric, a coverage metric, a sampling metric, or the like) has been achieved.

The test run results 358 may comprise various metrics, axes values, or the like. The test run results 358 may include one or more of stack or environment logs. The test run results 358 may include various data files such as sensor and render data files. The test run results 358 may be provided to the post-processing service 350a. The post-processing service 350a may be configured to convert, at an internal parameter format converter plugin, axes data in a time-based metrics signal format into internal parameter format data. The axes data, which may be in a time-based metrics signal format or an internal parameter format, may be written to a database. The database may be used when retrieving one or more axes values for the testing modality (e.g., SIL, HIL, track), and when computing one or more axes-specific metrics based on the one or more axes values. Data storage in an internal parameter format may facilitate efficient data retrieval when performing computations. Alternatively, or in addition, the computations may be vectored to facilitate computational efficiency.

The test run results 358 may be processed in various operations to generate a data probability distribution to be sent to the intelligent job manager 340c. The data probability distribution may be computed using a parametric metric (e.g., a metric that is based on one or more parameters). The parametric metric may be computed using one or more of a parametric performance metric or a parametric coverage metric. The parametric metric may be based on a particular use case type.

The parametric metric (e.g., a tunable exploration metric) may be used to explore the information space that may be tested. In one example, the parametric metric may be tuned based on the difference between a random sample and the sample that has been collected. For example, for a uniform discrete distribution between 1 and 10, a heavy weighting of samples near the upper end of the range may indicate that samples near the lower end of the range may be explored. The tunable exploration metric may be adjusted as samples near the lower end of the distribution are collected. That is, the tunable exploration metric may be used to determine the degree of samples that fall outside of a distribution and may be adjusted as the distribution changes in response to sample collection.

Alternatively, or in addition, the parallel job scheduler 340b may be configured to generate subsequent test sample batches based on one or more axes-specific metrics. The one or more axes-specific metrics may be based on one or more axes values selected based on the parametric metric.

The parallel job scheduler 340b may be configured to schedule jobs using asynchronous information (e.g., asynchronous test results). The parallel job scheduler 340b may be configured to schedule one or more different test samples in parallel and terminate, adjust, or add different test samples using asynchronous information (e.g., asynchronous test results). The parallel job scheduler 340b may terminate, adjust, or add different test samples using asynchronous information (e.g., asynchronous test results) without having a completion time for particular test samples. The parallel job scheduler 340b may receive additional test samples for testing based on asynchronous information (e.g., asynchronous test results) before previous test samples have completed testing.

A device for testing, simulating, or validating a vehicle may comprise a memory and a processor. The processor may be configured to execute instructions to cause the device to test a first test sample batch that includes one or more first test samples to output one or more first test sample results. The plurality of first test sample results may include test samples that have completed (which may be used as asynchronous information) and samples that have not been completed (and therefore may not be used as asynchronous information). The plurality of first test sample results may be generated using one or more different testing modalities (e.g., SIL, HIL, track, or the like).

The processor may be configured to identify one or more asynchronous test sample results of the plurality of first test samples before the first test sample batch is complete. That is, the asynchronous test sample results may be test sample results that have been completed even though the first test sample batch further includes incomplete test sample results. The asynchronous test sample results may be based on real world data. One or more asynchronous test sample results may be used to compute a parametric metric.

The parametric metric may comprise one or more of a parametric performance metric or a parametric coverage metric. The first sample batch may be terminated before completion based on the parametric metric. The parametric metric may be used to adjust the second test sample batch. The second test sample batch may be adjusted based on test adjustment configuration parameters including one or more of: a learning rate decay parameter, a sample size parameter, a hyper parameter, an algorithm selection parameter, or the like.

The parallel job scheduler 340b may be configured to convert the plurality of first test samples from an internal parameter format to a testing modality format. For example, the internal parameter format may be converted to a HIL format (e.g., using a HIL plugin), to a SIL format (e.g., using a SIL plugin), or to a field test format (e.g., using a field test plugin).

The plurality of first test samples may be in a test modality format when the asynchronous information is being identified. The asynchronous information (e.g., the one or more asynchronous test sample results) may be converted to an internal parameter format from the testing modality format (when present in the testing modality format). Converting the asynchronous information to an internal parameter format may minimize the computational complexity, computation time, and expense of adjusting the second test sample batch based on the asynchronous information.

### Metrics

A device for vehicle simulation, vehicle testing, or vehicle validation may comprise a memory and a processor operatively coupled to the memory. The processor may be configured to execute instructions to cause the device to identify a first parameter set defined using a first scenario format. The first parameter set may comprise one or more of: one or more first scenario format axes; one or more first scenario format relationships; or one or more first scenario format constraints.

As illustrated in FIG. 4A, functionality 400a is provided in which the post-processing service 450a may be configured to identify the first parameter set. The post-processing service 450a may be configured to map the first parameter set to an internal parameter set. The internal parameter set may comprise one or more of: one or more internal axes, one or more internal relationships, or one or more internal constraints. The post-processing service may be configured to convert the first parameter set (e.g., the test run results) to generate the internal parameter set (e.g., test agnostic data points 451). The internal parameter set (e.g., test agnostic data points 451) may be input to the sampling service 450b.

The sampling service 450b may be configured to compute asynchronous information to be provided to the intelligent job manager 340c (e.g., as illustrated in FIG. 3A). The sampling service 450b may be configured to identify one or more asynchronous test sample results of one or more first test samples before a first test sample batch has finished testing. The sampling service 450b may be configured to compute a parametric metric. The parametric metric may be based on one or more of a parametric performance metric or a parametric coverage metric. The sampling service 450b may be configured to select a set of algorithms based on the parametric metric. The sampling service 450b may be configured to apply an algorithm of the set of algorithms to a second test sample batch before the first test sample batch has finished testing.

The sampling service 450b may be configured to generate and adjust an information space that may comprise the internal parameter set by adding data indexes based on one or more of: (i) one or more internal axes values, (ii) one or more internal relationship values, or (iii) one or more internal constraint values.

The sampling service 450b may be configured to select one or more of a set of axes based on a parametric metric, or a subset of the set of axes. A result based on one or more of the set of axes based on one or more of a parametric metric or the subset of the set of axes may be displayed on a display device. One or more axes values for the set of axes or the subset of the set of axes may be retrieved for a specific testing modality (e.g., HIL, SIL, track, or the like), and one or more axes-specific metrics may be computed based on the set of axes or the subset of the set of axes.

The sampling service 450b may be configured to compute a parametric metric. The parametric metric may be based on one or more of a parametric performance metric or a parametric coverage metric. The parametric metric may be based on a particular use case type. The sampling service 450b may be configured to generate a test configuration object based on one or more axes-specific metrics. The one or more axes-specific metrics may be based on one or more axes values selected based on the parametric metric. A result based on the parametric metric may be displayed on a display device.

As illustrated in FIG. 4B, various operations 400b show that the sampling service 450b may send the test agnostic data points to a data indexing block 460a that may be configured to process the test agnostic data points 461 by: constructing primary indexes (as shown in block 462), and constructing secondary indexes (i.e., views) (as shown in block 464). The primary indexes may include one or more of: (a) a date, (b) an axis, (c) a test environment, (d) a stack version, (e) other metadata, or the like (as shown in block 463).

The secondary indexes of the construct secondary indexes block 464 may be activated based on user input or based on the availability of computational resources. The construct secondary indexes block 465 may generate a group of primary indexes which may include filtered values configured to select specific values, ranges, or the like of the test agnostic data points.

The test agnostic data points 461 may be sent to a featurization block 460b which may process the test agnostic data points 461 to generate a result to be sent in a feedback loop to one or more of: (i) the test agnostic data points 461, block 463, or block 465. As illustrated in FIG. 4C, further operations 400c may include sending the test agnostic data points 461 to the featurization block 460b that may be input to an apply kernel functions block 466. The kernel functions may be applied to the test agnostic data points to generate a feature vector 468. Different techniques may be used to generate the feature vector 468 including one or more of: (i) linear, (ii) non-linear, (iii) deep learning based functions, (iv) frequency-space transforms, (v) other transformations, or the like, as shown in block 467. The output of the featurization block 460b (e.g., a feature vector 468) may be sent to the data indexing block 460a (e.g., to the test agnostic data points 461, block 463, or block 465.

The sampling service 450b may generate test agnostic data points and indexes 453 using data indexing in block 460a, and featurization 460b, as illustrated in FIG. 4A. The test agnostic data point and indexes 453 may be sent to an inference service 450c. The inference service 450c may be configured to filter test agnostic data points into a multi-dimensional distribution. The test agnostic data points and indexes 453 may be filtered into a multi-dimensional distribution based on one or more of relevance or based on various data point spaces that may use one or more primary indexes, secondary indexes, features, or the like to generate a data point probability distribution 480. The data point probability distribution 480 may be sent for distribution post-processing 460c.

A user interface may be provided to allow a user to view one or more of the vehicle stack performance, test coverage, or uncertainty/test gaps at a glance via a web-based viewer. Via the user interface, a user may select any axes or combinations of axes (e.g., performance metrics, such as pass rate, time to collision, variables, such as weather, driving speed, road type, etc.). Multi-dimensional charts of test results related to a set of axes may be displayed via the user interface (e.g., scatterplot matrices, clustered scatterplots, surface/contour plots, or the like) based on a selection on the user interface. Via the user interface, filters and switch axes may be applied on these charts to iteratively filter the information space (e.g., the stacks performance, the test coverage, the uncertainty/test gaps, or the like).

In some examples, users may click on recommendations of coverage gaps, high correlation axes, relationships, clusters, and high uncertainty, and low metric values. A user may select a combination of one or more of axes, grouping, clustering, smoothing, interpolation, or statistical metrics to view by sending a request to the sampling service 450b. The sampling service 450b may attempt to retrieve axes values for particular testing modalities (e.g., SIL, HIL, track, or the like). When an axis is not present for particular testing modalities, the axis values may be computed as requested, and the sampling service 450b may provide the user interface with one or more of the vehicle stack performance, test coverage, test gaps, or the like. Alternatively, or in addition, the sampling service 450b may provide the user interface with one or more of the vehicle stack performance, test coverage, test gaps, or the like when the axis for a particular testing modality is present.

When axes-values have been computed, the distribution post-processing 460c operation may be configured to facilitate various operations to send data to the probability distribution 470 operation and receive the data point probability distribution 480 as shown in the operations 400d illustrated in FIG. 4D. The data point probability distribution 480 may be augmented with kernel functions, as shown in block 469a, or the data point probability distribution 480 may be used to compute derived distributions, as shown in block 469b.

When the data point probability distribution 480 is augmented with kernel functions, a data point probability distribution 469c may be computed. When the data point probability distribution 480 is used to compute derived distributions, then one or more of gradients 469d or density 469e may be computed. One or more of the data point probability distribution 469c, the gradients 469d, or the density 469e may be used to perform statistical analysis, as shown in the block 469f.

The performed statistical analysis may comprise any suitable technique to generate a probability distribution including one or more of: (i) clustering, (ii) regression, (iii) important (e.g., based on a combination of coverage and/or performance), (iv) sensitivity analysis, or (v) entropy, as shown in block 469g. The distribution post-processing 460c operation may provide an input to the probability distribution 470 operation for further processing to the intelligent job manager 440c.

The performed statistical analysis may comprise any suitable analytical technique for analyzing the data point probability distribution. The performed statistical analysis may include grouping combinations of axes values for further computation based on one or more of metadata tags, scenarios, drive tags, location, or the like. Alternatively, or in addition, derivative metrics may be computed (e.g., confidence, confidence interval, average, minimum, maximum, count, standard deviation, statistical entropy, or the like). Alternatively, or in addition, clustering and correlation analysis may be performed to determine patterns. Example patterns may include linear kernel separators, Kernel-based correlation analysis, K-means clustering, DB-SCAN clustering, or the like. Alternatively, or in addition, outliers, clusters, and related metrics may be linked to these results. Alternatively, or in addition, smoothing and interpolation may be performed including one or more of Gaussian smoothing, linear interpolation, nearest neighbors interpolation, cubic interpolation, quintic interpolation, or the like.

The user interface may provide for page filtering for particular scenarios, simulations, drives or the like. Input to the user interface may be submitted to the scenario cross compiler 310, as illustrated in FIG. 3A, to be compiled into scenarios and test cases in a specific testing modality (e.g., HIL, SIL, track, or the like). A test modality specific plugin may be configured to compile an internal parameter set (in an internal parameter format) to a test modality format that may include a base external scenario.

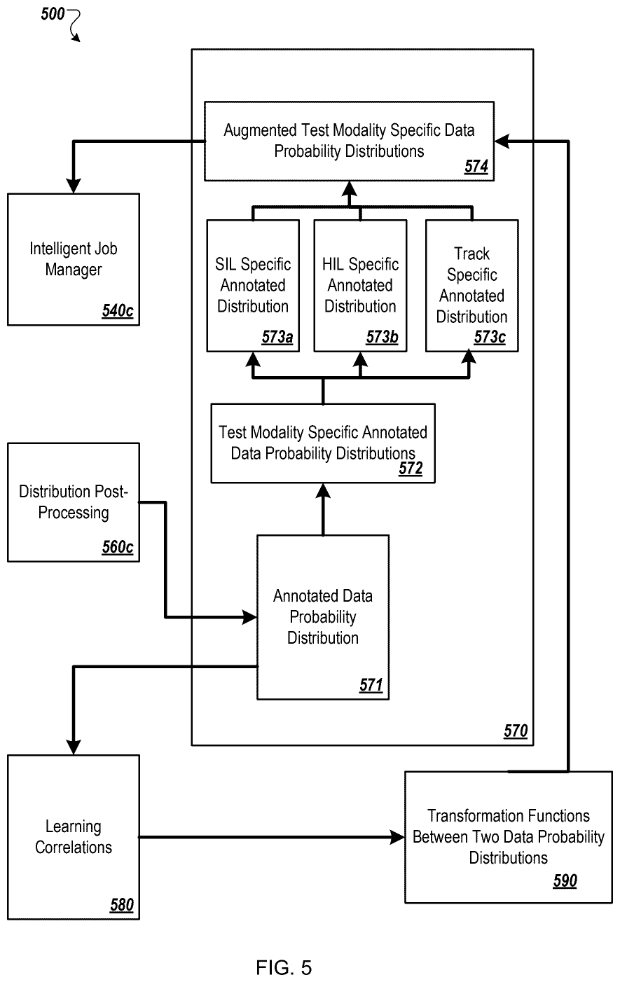

The output from the distribution post-processing block 560c, as illustrated in the block diagram 500 in FIG. 5, may be sent to the probability distribution block 570 (e.g., the annotated data probability distribution block 571). The annotated data probability distribution block 571 may be a data probability distribution that may be used to compute a metric using, e.g., an internal parameter set. The metric may comprise one or more of a performance metric or a coverage metric. The metric may be based on a use case type. The metric may be computed using one or more of: a confidence level, a confidence interval, a normalized format, or a sample density.

The annotated data probability distribution block 571 may be configured to identify the particular driving situations based on one or more of: (i) importance (e.g., high-sensitivity), (ii) density relative to importance (e.g., may use further data collection), (iii) correlating variables (e.g., regression), (iv) clustering (e.g., discrete patterns), or the like. These metrics (e.g., importance, density relative to importance, correlating variables, clustering, or the like) may be used to select axes for additional testing.

The metric may be a unified metric that may be computed based on the performance metric and the coverage metric. The unified metric may be based on one or more of: an objective function (e.g., Boolean or continuous) or real-world data. The unified metric may be a single metric that facilitates a determination of performance and coverage for a unified parameter space. That is, the unified metric may be used for one or more of verification or auditing of one or more of performance or coverage with respect to the unified parameter space. In one example, a query may include: “Does my stack prevent collisions in hard braking events with 99.99% success and 0.01% margin of error?” In response to the query, a set of statistical metrics (e.g., metrics, metrics, unified metrics, or the like) may be returned that accept or reject the query.

A vehicle safety characteristic may be queried and/or audited using quantification. The annotated data probability distribution block 571 may be used to query a vehicle safety characteristic, and compute, in response to the vehicle safety characteristic query, a safety metric based on the metric.

The metric may be computed using parallelization to maximize one or more of the operational design domain (ODD) coverage or the ODD performance. The annotated data probability distribution block 571 may be used to determine an ODD coverage for an autonomous vehicle based on the metric. The annotated data probability distribution block 571 may be used to determine an ODD performance for an autonomous vehicle based on the metric. That is, the metric may be used to evaluate the coverage and/or performance of a set of tests over a vehicle's stack (e.g., an autonomous vehicle's stack) target ODD. The metric may be used to selected one or more sampling algorithms to optimize parallelization to maximize subsequent metrics (e.g., metrics, unified metrics, or the like).

The metric may be used to determine a particular test that may be used to facilitate the collection of data to maximize one or more of the performance or coverage of the unified parameter space. In one example, the metric may indicate that light detection and ranging (LIDAR) may be used to increase one or more of performance or coverage of the unified parameter space. In another example, a user interface may accept input that may select a particular test based on a particular use case. A selected number of different algorithms and/or metrics associated with one or more tests may be provided to facilitate data collection. The user interface may receive an input to select one or more of a particular test (e.g., LIDAR), a particular algorithm, a particular metric, or the like.

The metric may be used with an internal parameter format to minimize the data collection time and computational resources and maximize the quality of the data collected. A device for vehicle testing may comprise a memory and a processor operatively coupled to the memory. The processor may be configured to execute instructions to cause the device to identify a first parameter set defined using a first scenario format, where the first parameter set includes one or more first scenario format axes, one or more first scenario format relationships; and one or more first scenario format constraints. The processor may be configured to execute instructions to cause the device to map the first parameter set to an internal parameter set, where the internal parameter set includes one or more internal axes, one or more internal relationships, and one or more internal constraints. The processor may be configured to execute instructions to cause the device to compute a metric, where the metric is based on one or more of a performance metric or a coverage metric. The device may comprise a display device configured to display a result based on the metric. The metric may be based on a use case type.

The annotated data probability distribution block 571 may be used to provide the metric to a sampling service (e.g., sampling service 450b as illustrated in FIG. 4A) and/or an inference service (e.g., inference service 450c as illustrated in FIG. 4A). The sampling service 450b and/or the inference service 450c may be configured to one or more of: (i) select a set of axes based on the metric; (ii) display a result based on the set of axes on the display device; (iii) select a subset of the set of axes; or (iv) display a subset of the result based on the subset of the set of axes on the display device. The sampling service 450b and/or the inference service 450c may be configured to: retrieve one or more axes values for one or more testing modalities, and compute one or more axes-specific metrics based on the one or more axes values. The axes-specific metrics based on one or more axes values based on e.g., the metric, may be sent to the scenario cross compiler 310 for sending to the linker service 330 to generate a test configuration object.

The metric may be used with asynchronous test sample results to minimize the testing time and computational resources and maximize one or more of the coverage or performance of subsequent testing results. A device for vehicle simulation, testing, or validation may comprise a memory and a processor operatively coupled to the memory. The processor may be configured to execute instructions to cause the device to one or more of: (i) test a first test sample batch that includes one or more first test samples to output one or more first test sample results, (ii) identify one or more asynchronous test sample results of the plurality of first test samples before the first test sample batch is complete, (iii) compute a metric based on the one or more asynchronous test sample results, where the metric includes one or more of a performance metric or a coverage metric, or (iv) adjust a second test sample batch based on the metric.

The processor may be configured to determine the one or more asynchronous test sample results based on a parametric metric that may include one or more of a parametric performance metric or a parametric coverage metric. The asynchronous test sample results may be determined based on real world data.

The first test sample result may be generated using one or more different testing modalities (e.g., SIL, HIL, track, or the like). The first test samples may be converted from an internal parameter format to a testing modality format. The asynchronous test sample results, which may be selected from the first sample batch, may be converted to the internal parameter format from the testing modality format.

The metric may be used to terminate the first sample batch before the first sample batch has completed testing. The metric may be used to adjust the second test sample batch based on test adjustment configuration parameters including one or more of: the selected sampling algorithm, a randomness parameter, or other hyper parameters such as a learning rate decay parameter or a sample size parameter.

The annotated data probability distribution block 571, as illustrated in FIG. 5, may be sent to the test modality specific annotated data probability distributions block 572 which may be configured to generate various test modality specific distributions and sub-distributions including: (i) a SIL specific annotated distribution 573a, (ii) a HIL specific annotated distribution 573b, (iii) a track specific annotated distribution 573c, or the like. These test modality specific annotated distributions (e.g., 573a, 573b, 573c) may be sent to the augmented test modality specific data probability distribution block 574 to be sent to the intelligent job manager 540c.

The augmented test modality specific data probability distribution block 574 may include one or more of distributions or sub-distributions for one or more of SIL, HIL, drive data or the like. The augmented test modality specific data probability distribution block 574 may be augmented by various tests performed using the transformation functions between two data probability distributions block 590 by including factors relating to increased variance and/or uncertainty arising from the transformation.

The annotated data probability distribution block 571 may be configured to send the annotated data probability distribution to a learning correlation block 580 for processing. The output from the learning correlation block 580 may be sent to a transformation function between two data probability distributions block 590, which may be configured to be output to the augmented test modality specific data probability distribution block 574.

### Transformation Functions Between Testing Modalities

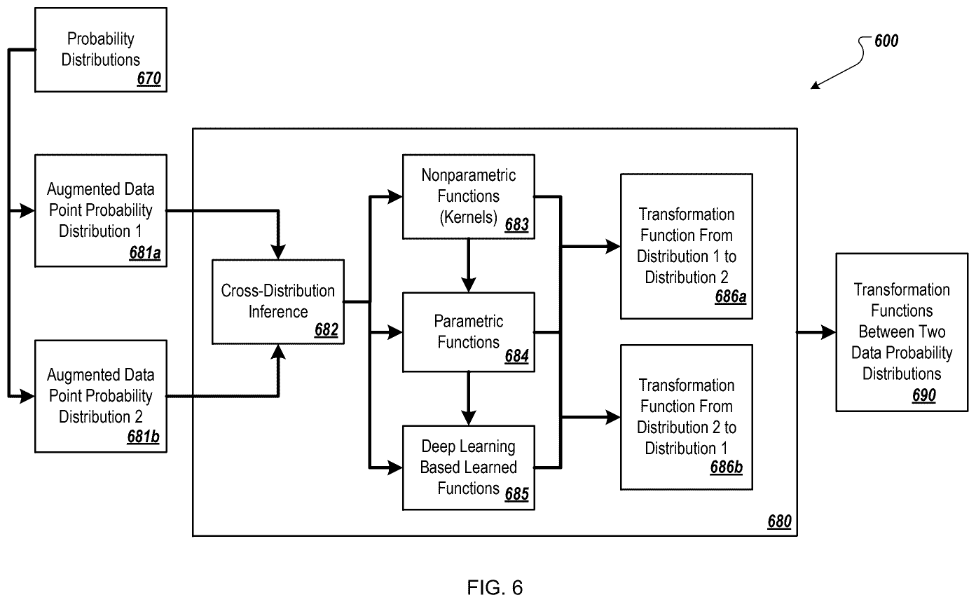

A device for vehicle testing, simulation, and validation may comprise a memory and a processor. The processor may be configured to execute instructions to cause the device to identify first test data based on a first test modality, where the test data includes one or more of first coverage test data, first performance test data, first metric distribution test data, or first uncertainty test data. For example, the learning correlation block 580 may be configured to receive data from the annotated data probability distribution block 571, as illustrated in FIG. 5. The data provided to the learning correlation block 680 from the probability distributions block 670, as illustrated in FIG. 6, may be one or more augmented data point probability distributions (e.g., augmented data point probability distribution 1, 681a, and augmented data point probability distribution 2, 681b).

A transformation function may be generated to switch between different test data modalities. The processor may be configured to execute instructions to cause the device to compute a transformation function configured to transform the test data from the first test modality to a second test modality, where the second test modality is different from the first test modality. For example, a cross-distribution inference block 682 may be configured to generate transformation functions 686a, 686b: (i) a transformation function from augmented data point probability distribution 1, 681a, to augmented data point probability distribution 2, 681b, and (ii) a transformation function from augmented data point probability distribution 2, 681b, to augmented data point probability distribution 1, 681a. The transformation functions 686a, 686b may be generated using any suitable functions including one or more of: (a) nonparametric functions 683 (e.g., kernels), (b) parametric functions 684, or (c) deep learning based learned functions 685.

The transformation function may be used to compute test data in a testing modality (e.g., second test data in a second testing modality) that differs from the testing modality of the received testing data (e.g., the first test data in a first testing modality). The processor may be configured to compute, using the transformation function, second test data based on the first test data, where the second test data includes one or more of second coverage test data, second performance test data, second metric distribution test data, or second uncertainty test data. The first test modality may be any suitable testing modality including one or more of: SIL, HIL, tracking testing, or the like. The second test modality may be any suitable testing modality including one or more of: SIL, HIL, tracking testing, or the like.

A number of metrics may be computed to compare the differences between the first test data and the second test data that may occur as a consequence of generating the second test data using the first test data and a transformation function between the first test data and the second test data. These metrics may include: (i) an information loss metric to determine the amount of information loss that occurs when the first test data is transformed to the second test data using the transformation function, (ii) a risk metric to determine the amount of risk that occurs when the first test data is transformed to the second test data using the transformation function, or (iii) an uncertainty metric to determine the amount of uncertainty that occurs when the first test data is transformed to the second test data using the transformation function.

Some of the metrics may be used to determine the reduction in one or more of a testing time or computational complexity that may occur when a transformation function is used in comparison to when a transformation function is not used. A processor may be configured to compute one or more of a transformation testing time or a transformational computational complexity to compute the second test data, using the transformation function, based on the first test data. The processor may be configured to compute one or more of a non-transformation testing time or a non-transformation computational complexity to compute the second test data without using the transformation function and the first test data. The processor may be configured to compute one or more of a test time savings or a computational complexity savings based on the difference between: (i) the transformation testing time and the non-transformation testing time, or (ii) the transformation computational complexity and the non-transformation computational complexity.

The transformation function may be used to categorize to determine the ODD space. For example, when testing for different weather conditions, a sunny test scenario may be performed using sunny weather and a rainy test scenario may be performed using rainy weather. The transformation function may be configured to transform one or more of the sunny test scenario or the rainy test scenario to gather data relating to the test scenarios for additional weather conditions (e.g., snowy, windy, dark, or the like).

The output of the leaning correlation block 680 (e.g., transformation functions between two data probability distributions 690) may be provided to the probability distribution block 570 (e.g., the annotated data probability distribution block 571), illustrated in FIG. 5, to be sent to the augmented test modality specific data probability distribution 574. The output of the test modality specific annotated data probability distributions (e.g., 573a, 573b, 573c) may be provided to the augmented test modality specific data probability distribution 574. The augmented test modality specific data probability distribution 574 may be sent to the intelligent job manager 540c.

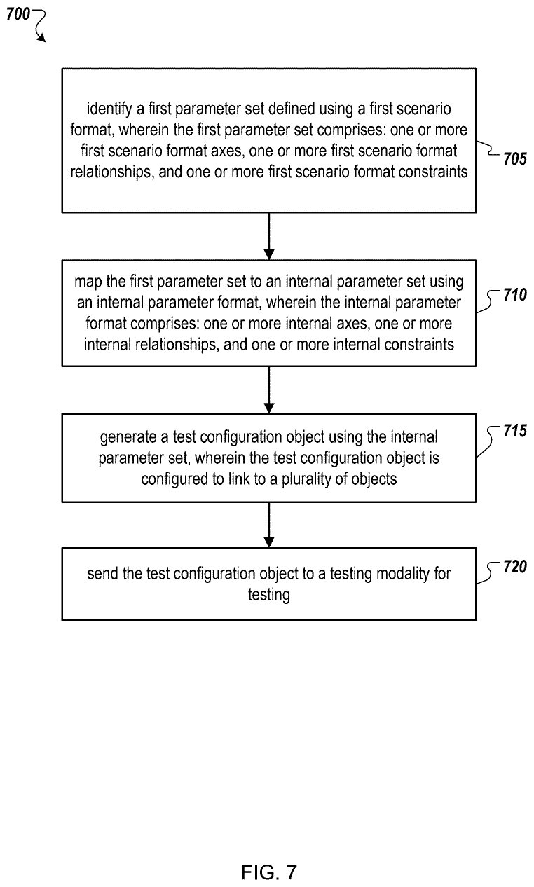

FIG. 7 illustrates a process flow of an example method 700 that may be used for vehicle testing, simulation, or validation, in accordance with at least one example described in the present disclosure. The method 700 may be arranged in accordance with at least one example described in the present disclosure.

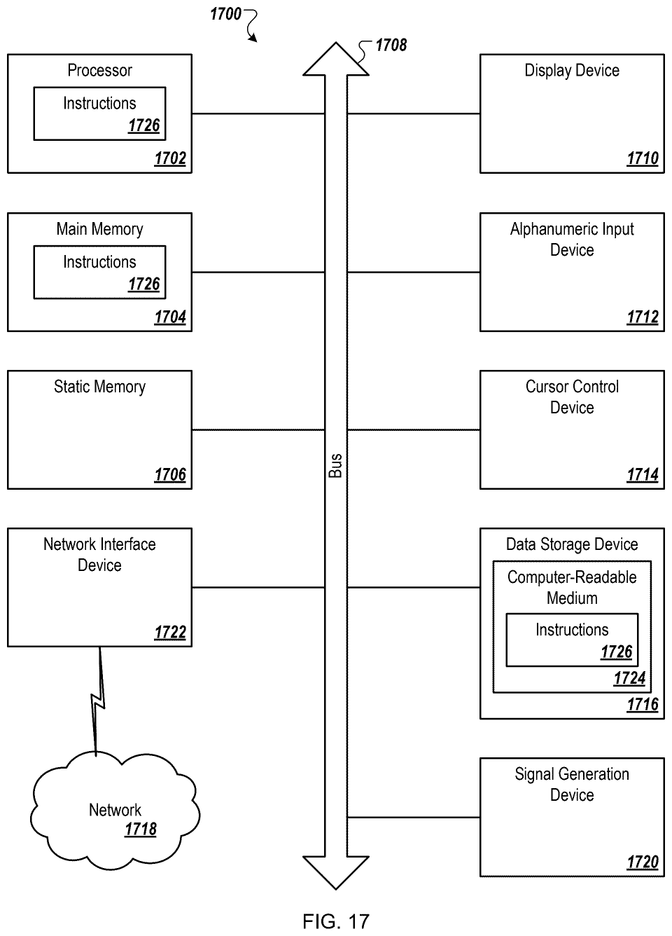

The method 700 may be performed by processing logic that may include hardware (circuitry, dedicated logic, etc.), software (such as is run on a computer system or a dedicated machine), or a combination of both, which processing logic may be included in the processing device (e.g., a processor) 1702 of FIG. 17, or another device, combination of devices, or systems.

The method 700 may begin at block 705 where the processing logic may identify a first parameter set defined using a first scenario format, where the first parameter set includes one or more first scenario format axes, one or more first scenario format relationships, and one or more first scenario format constraints.

At block 710, the processing logic may map the first parameter set to an internal parameter set using an internal parameter format, where the internal parameter format includes one or more internal axes, one or more internal relationships, and one or more internal constraints.

At block 715, the processing logic may generate a test configuration object using the internal parameter set, where the test configuration object is configured to link to one or more objects.

At block 720, the processing logic may send the test configuration object to a testing modality for testing.

The processor may be further configured to execute instructions to cause the device to perform one or more of: identify a compilation source in the internal parameter format to map the internal parameter set to the first parameter set; identify a metric in the internal parameter format after testing; format the test configuration object into a testing modality format for the testing modality; send the test configuration object to a testing modality associated with the testing modality; convert, at an internal parameter format converter plugin, testing modality format data into internal parameter format data; or convert, at an internal parameter format converter plugin, axes data in a time-based metrics signal format into internal parameter format data; or write the axes data to a database. The testing modality may include one or more of: a particular scenario language simulator, a software in the loop (SIL) simulator plugin interface, a hardware in the loop (HIL) simulator plugin interface, or a track testing plugin interface. The first scenario format may comprise an open scenario format that may comprise an OSC definition language.

Modifications, additions, or omissions may be made to the method 700 without departing from the scope of the present disclosure. For example, in some examples, the method 700 may include any number of other components that may not be explicitly illustrated or described.

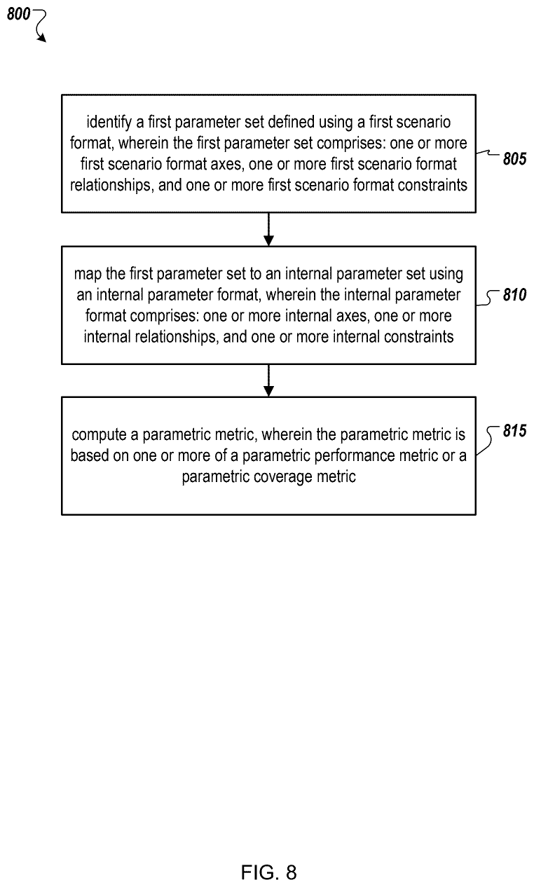

FIG. 8 illustrates a process flow of an example method 800 that may be used for vehicle testing, simulation, or validation, in accordance with at least one example described in the present disclosure. The method 800 may be arranged in accordance with at least one example described in the present disclosure.

The method 800 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 800 may begin at block 805 where the processing logic may identify a first parameter set defined using a first scenario format, where the first parameter set includes one or more first scenario format axes, one or more first scenario format relationships, and one or more first scenario format constraints.

At block 810, the processing logic may map the first parameter set to an internal parameter set, where the internal parameter set includes one or more internal axes, one or more internal relationships, and one or more internal constraints.

At block 815, the processing logic may compute a parametric metric, where the parametric metric is based on one or more of a parametric performance metric or a parametric coverage metric.

The processor may be further configured to execute instructions to cause the device to perform one or more of: select a set of axes based on the parametric metric; display a result based on the set of axes on a display device; or select a subset of the set of axes; display a subset of the result based on the subset of the set of axes on the display device; retrieve one or more axes values for one or more testing modalities; compute one or more axes-specific metrics based on the one or more axes values; or generate a test configuration object based on one or more axes-specific metrics, where the one or more axes-specific metrics are based on one or more axes value selected based on the parametric metric. The parametric metric may be based on a use case.

Modifications, additions, or omissions may be made to the method 800 without departing from the scope of the present disclosure. For example, in some examples, the method 800 may include any number of other components that may not be explicitly illustrated or described.

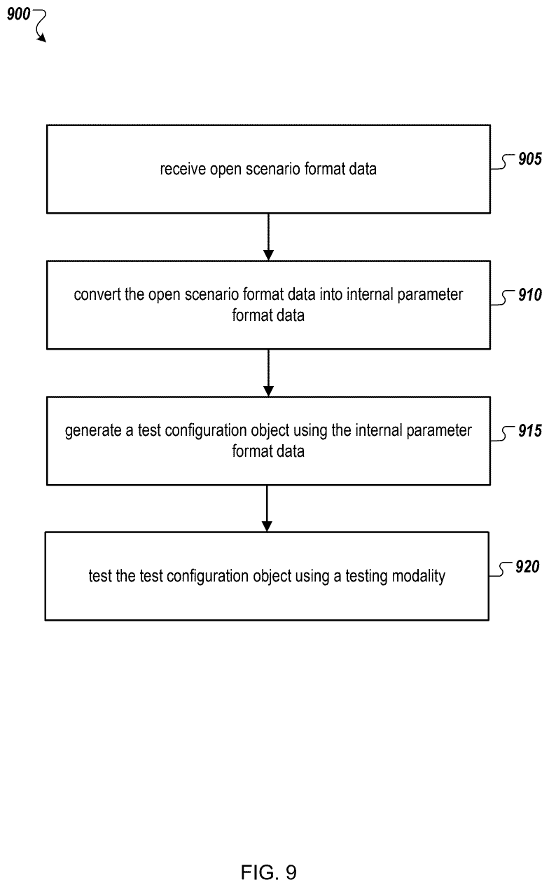

FIG. 9 illustrates a process flow of an example method 900 that may be used for vehicle testing, simulation, or validation, in accordance with at least one example described in the present disclosure. The method 900 may be arranged in accordance with at least one example described in the present disclosure.

The method 900 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 900 may begin at block 905 where the processing logic may receive scenario format data.

At block 910, the processing logic may convert the scenario format data into internal parameter format data.

At block 915, the processing logic may generate a test configuration object using the internal parameter format data.

At block 920, the processing logic may test the test configuration object using a testing modality.

The processor may be further configured to execute instructions to cause the device to perform one or more of: format the test configuration object into a testing modality format for the testing modality; send the test configuration object to a testing modality associated with the testing modality, where the testing modality includes one or more of a particular scenario format simulator, a software in the loop (SIL) simulator plugin interface, a hardware in the loop (HIL) simulator plugin interface, or a track testing plugin interface; convert, at an internal parameter format converter plugin, testing modality format data into internal parameter format data; convert, at an internal parameter format converter plugin, axes data in a time-based metrics signal format into internal parameter format data; write the axes data to a database; compute a parametric metric, where the parametric metric is based on one or more of a parametric performance metric or a parametric coverage metric, where the parametric metric is based on a use case; retrieve one or more axes values for the testing modality; compute one or more axes-specific metrics based on the one or more axes values; generate the test configuration object based on one or more axes-specific metrics, where the one or more axes-specific metrics are based on one or more axes value selected based on the parametric metric.

Modifications, additions, or omissions may be made to the method 900 without departing from the scope of the present disclosure. For example, in some examples, the method 900 may include any number of other components that may not be explicitly illustrated or described.

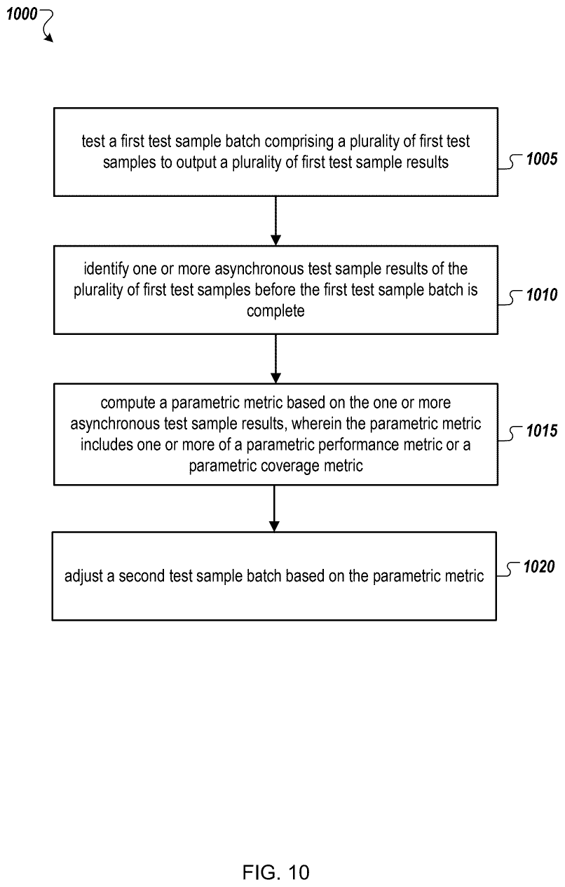

FIG. 10 illustrates a process flow of an example method 1000 that may be used for vehicle testing, simulation, or validation, in accordance with at least one example described in the present disclosure. The method 1000 may be arranged in accordance with at least one example described in the present disclosure.

The method 1000 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1000 may begin at block 1005 where the processing logic may test a first test sample batch that includes one or more first test samples to output one or more first test sample results.

At block 1010, the processing logic may identify one or more asynchronous test sample results of the plurality of first test samples before the first test sample batch is complete.

At block 1015, the processing logic may compute a parametric metric based on the one or more asynchronous test sample results, where the parametric metric includes one or more of a parametric performance metric or a parametric coverage metric.

At block 1020, the processing logic may adjust a second test sample batch based on the parametric metric.

The processor may be further configured to execute instructions to cause the device to perform one or more of: determine the one or more asynchronous test sample results based on a parametric metric that includes one or more of a parametric performance metric or a parametric coverage metric; determine the one or more asynchronous test sample results based on real world data; terminate the first sample batch based on the parametric metric; convert the plurality of first test samples from an internal parameter format to a testing modality format; convert the one or more asynchronous test sample results to the internal parameter format from the testing modality format; adjust the second test sample batch based on test adjustment configuration parameters including one or more of: a learning rate decay parameter, a sample size parameter, a hyper parameter, an algorithm selection parameter, or the like. The plurality of first test sample results may be generated using one or more different testing modalities. Alternatively, or in addition, one or more subsequent test sample batches may be adjusted based on one or more previous test sample batches until a metric (e.g., a convergence metric, a confidence metric, a coverage metric, a sampling metric, or the like) has been achieved.

Modifications, additions, or omissions may be made to the method 1000 without departing from the scope of the present disclosure. For example, in some examples, the method 1000 may include any number of other components that may not be explicitly illustrated or described.

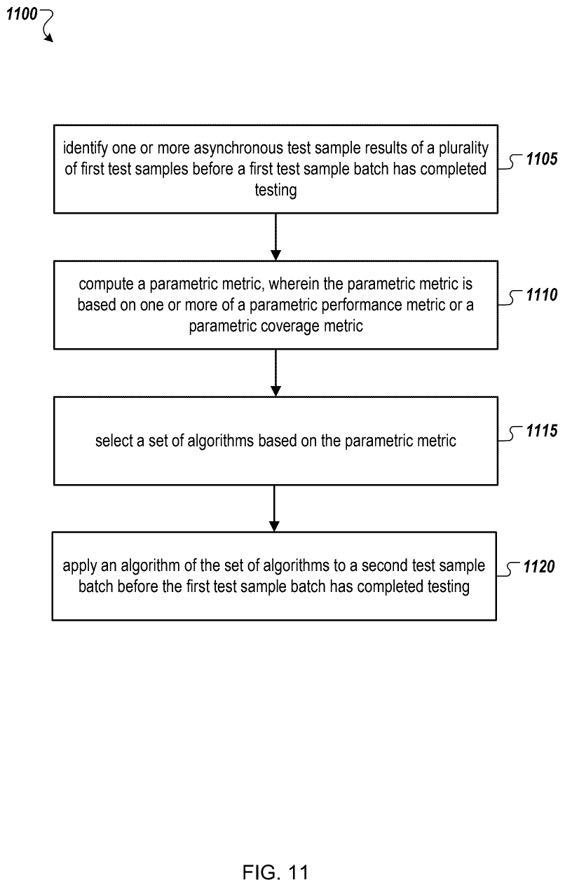

FIG. 11 illustrates a process flow of an example method 1100 that may be used for vehicle testing, simulation, or validation, in accordance with at least one example described in the present disclosure. The method 1100 may be arranged in accordance with at least one example described in the present disclosure.

The method 1100 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1100 may begin at block 1105 where the processing logic may identify one or more asynchronous test sample results of one or more first test samples before a first test sample batch has completed testing.

At block 1110, the processing logic may compute a parametric metric, where the parametric metric is based on one or more of a parametric performance metric or a parametric coverage metric.

At block 1115, the processing logic may select a set of algorithms based on the parametric metric.

At block 1120, the processing logic may apply an algorithm of the set of algorithms to a second test sample batch before the first test sample batch has completed testing.

The processor may be further configured to execute instructions to cause the device to perform one or more of: compute a parametric metric including one or more of: a confidence level, a confidence interval, a normalized metric, or sample density; select a set of axes based on the parametric metric; display a result based on the set of axes on a display device; select a subset of the set of axes; display a subset of the result based on the subset of the set of axes on the display device; retrieve one or more axes values for one or more testing modalities; compute one or more axes-specific metrics based on the one or more axes values; or generate a test configuration object based on one or more axes-specific metrics, where the one or more axes-specific metrics are based on one or more axes value selected based on the parametric metric. The parametric metric may be based on a use case. The parametric metric may be computed using one or more of an objective function or real world data. Alternatively, or in addition, one or more subsequent test sample batches may be adjusted based on one or more previous test sample batches until a metric (e.g., a convergence metric, a confidence metric, a coverage metric, a sampling metric, or the like) has been achieved.

Modifications, additions, or omissions may be made to the method 1100 without departing from the scope of the present disclosure. For example, in some examples, the method 1100 may include any number of other components that may not be explicitly illustrated or described.

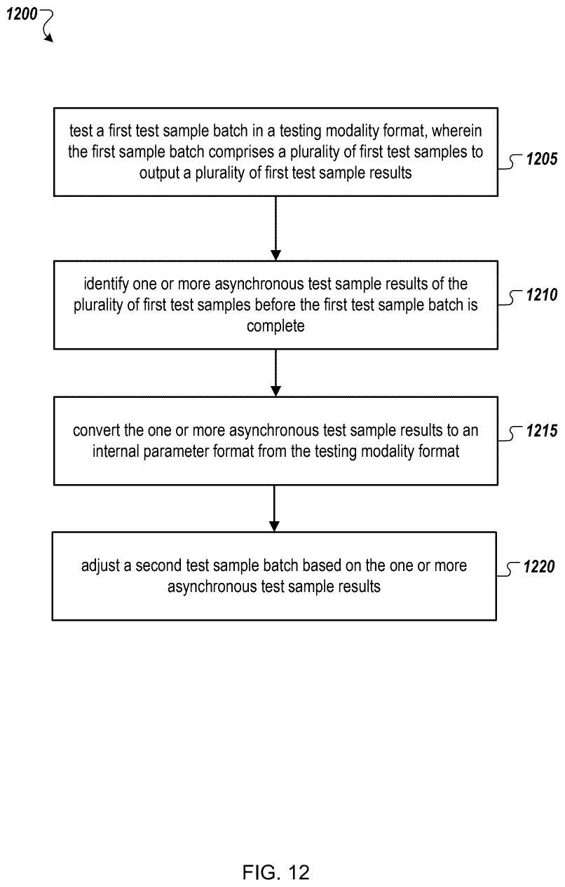

FIG. 12 illustrates a process flow of an example method 1200 that may be used for vehicle testing, simulation, or validation, in accordance with at least one example described in the present disclosure. The method 1200 may be arranged in accordance with at least one example described in the present disclosure.

The method 1200 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1200 may begin at block 1205 where the processing logic may test a first test sample batch in a testing modality format, where the first sample batch includes one or more first test samples to output one or more first test sample results.

At block 1210, the processing logic may identify one or more asynchronous test sample results of the plurality of first test samples before the first test sample batch is complete.

At block 1215, the processing logic may convert the one or more asynchronous test sample results to an internal parameter format from the testing modality format.

At block 1220, the processing logic may adjust a second test sample batch based on the one or more asynchronous test sample results.

The processor may be further configured to execute instructions to cause the device to perform one or more of: format the second test sample batch into a testing modality format for the testing modality; send the second test sample batch to a testing modality associated with the testing modality, where the testing modality includes one or more of a particular scenario format simulator, a software in the loop (SIL) simulator plugin interface, a hardware in the loop (HIL) simulator plugin interface, or a track testing plugin interface; convert, at an internal parameter format converter plugin, axes data in a time-based metrics signal format into the internal parameter format data; write the axes data to a database; compute a parametric metric, where the parametric metric is based on one or more of a parametric performance metric or a parametric coverage metric, where the parametric metric is based on a use case; retrieve one or more axes values for the testing modality; or compute one or more axes-specific metrics based on the one or more axes values; generate the second test sample batch based on one or more axes-specific metrics, where the one or more axes-specific metrics are based on one or more axes value selected based on a parametric metric. Alternatively, or in addition, one or more subsequent test sample batches may be adjusted based on one or more previous test sample batches until a metric (e.g., a convergence metric, a confidence metric, a coverage metric, a sampling metric, or the like) has been achieved.

Modifications, additions, or omissions may be made to the method 1200 without departing from the scope of the present disclosure. For example, in some examples, the method 1200 may include any number of other components that may not be explicitly illustrated or described.

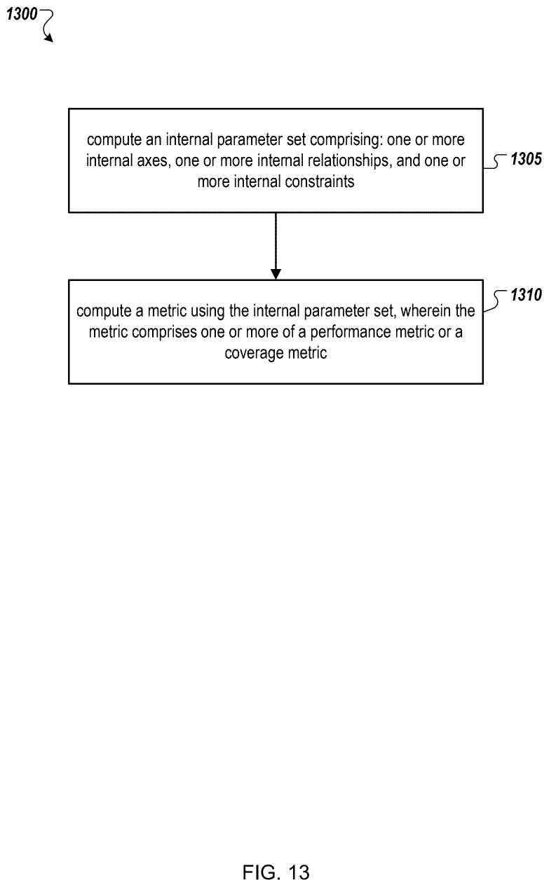

FIG. 13 illustrates a process flow of an example method 1300 that may be used for vehicle testing, simulation, or validation, in accordance with at least one example described in the present disclosure. The method 1300 may be arranged in accordance with at least one example described in the present disclosure.

The method 1300 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1300 may begin at block 1305 where the processing logic may compute an internal parameter set that includes one or more internal axes, one or more internal relationships, and one or more internal constraints.

At block 1310, the processing logic may compute a metric using the internal parameter set, where the metric includes one or more of a performance metric or a coverage metric.

The processor may be further configured to execute instructions to cause the device to perform one or more of: compute the metric based on a use case; compute the metric using one or more of: a confidence level, a confidence interval, a normalized format, or a sample density; determine an operational design domain (ODD) coverage for a vehicle based on the metric; determine an operational design domain (ODD) performance for a vehicle based on the metric; query a vehicle safety characteristic; compute, in response to the vehicle safety characteristic query, a safety metric based on the metric; compute the unified metric based on the performance metric and the coverage metric; compute the unified metric based on one or more of: an objective function or real-world data; or compute the metric using parallelization to maximize one or more of an operational design domain (ODD) coverage or an ODD performance.

Modifications, additions, or omissions may be made to the method 1300 without departing from the scope of the present disclosure. For example, in some examples, the method 1300 may include any number of other components that may not be explicitly illustrated or described.

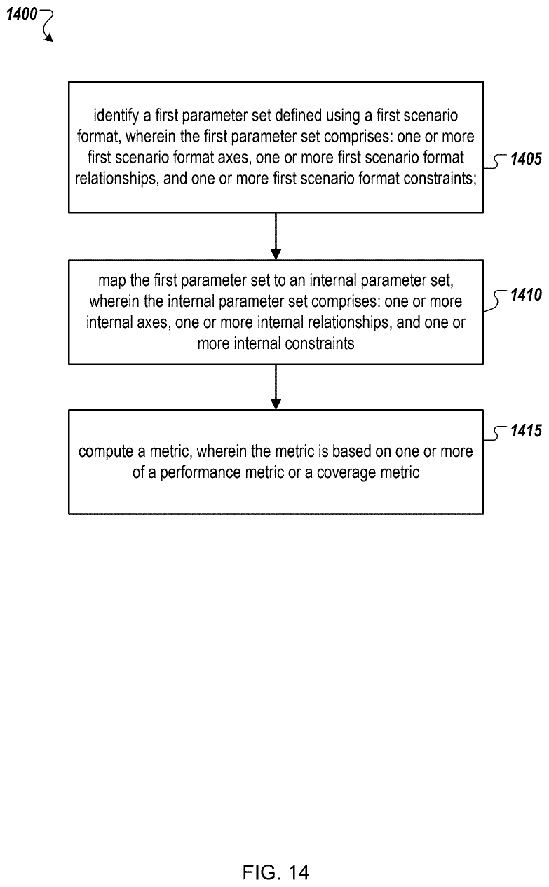

FIG. 14 illustrates a process flow of an example method 1400 that may be used for vehicle testing, simulation, or validation, in accordance with at least one example described in the present disclosure. The method 1400 may be arranged in accordance with at least one example described in the present disclosure.

The method 1400 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1400 may begin at block 1405 where the processing logic may identify a first parameter set defined using a first scenario format, where the first parameter set includes one or more first scenario format axes, one or more first scenario format relationships, and one or more first scenario format constraints.

At block 1410, the processing logic may map the first parameter set to an internal parameter set, where the internal parameter set includes one or more internal axes, one or more internal relationships, and one or more internal constraints.

At block 1415, the processing logic may compute a metric, where the metric is based on one or more of a performance metric or a coverage metric.

The processor may be further configured to execute instructions to cause the device to perform one or more of: select a set of axes based on the metric; display a result based on the set of axes on a display device; select a subset of the set of axes; display a subset of the result based on the subset of the set of axes on the display device; retrieve one or more axes values for one or more testing modalities; compute one or more axes-specific metrics based on the one or more axes values; or generate a test configuration object based on one or more axes-specific metrics, where the one or more axes-specific metrics are based on one or more axes value selected based on the metric. The metric may be based on a use case.

Modifications, additions, or omissions may be made to the method 1400 without departing from the scope of the present disclosure. For example, in some examples, the method 1400 may include any number of other components that may not be explicitly illustrated or described.

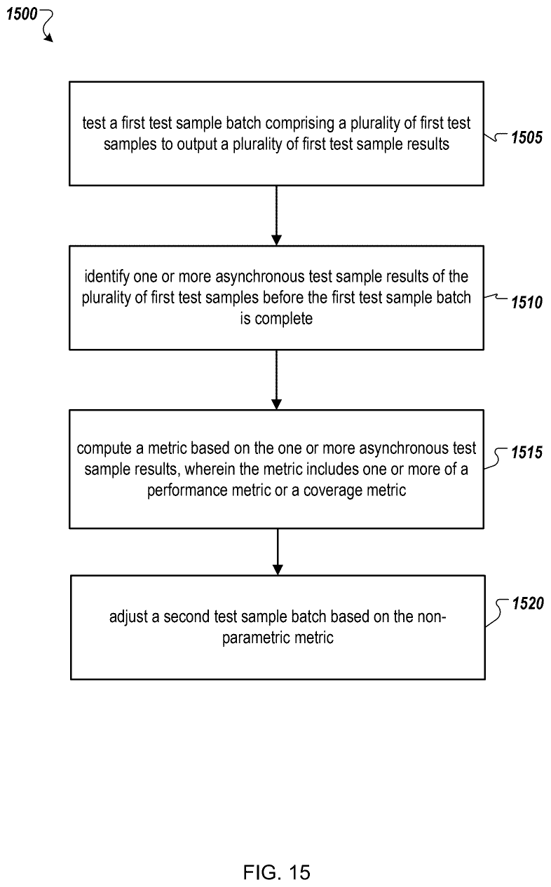

FIG. 15 illustrates a process flow of an example method 1500 that may be used for vehicle testing, simulation, or validation, in accordance with at least one example described in the present disclosure. The method 1500 may be arranged in accordance with at least one example described in the present disclosure.

The method 1500 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1500 may begin at block 1505 where the processing logic may test a first test sample batch that includes one or more first test samples to output one or more first test sample results.

At block 1510, the processing logic may identify one or more asynchronous test sample results of the plurality of first test samples before the first test sample batch is complete.

At block 1515, the processing logic may compute a metric based on the one or more asynchronous test sample results, where the metric includes one or more of a performance metric or a coverage metric.

At block 1520, the processing logic may adjust a second test sample batch based on the metric.

The processor may be further configured to execute instructions to cause the device to perform one or more of: determine the one or more asynchronous test sample results based on a parametric metric that includes one or more of a parametric performance metric or a parametric coverage metric; determine the one or more asynchronous test sample results based on real world data; terminate the first sample batch based on the metric; convert the plurality of first test samples from an internal parameter format to a testing modality format; convert the one or more asynchronous test sample results to the internal parameter format from the testing modality format; or adjust the second test sample batch based on test adjustment configuration parameters including one or more of: a learning rate decay parameter, a sample size parameter, a hyper parameter, an algorithm selection parameter, or the like. The first test sample results may be generated using one or more different testing modalities.

Modifications, additions, or omissions may be made to the method 1500 without departing from the scope of the present disclosure. For example, in some examples, the method 1500 may include any number of other components that may not be explicitly illustrated or described.

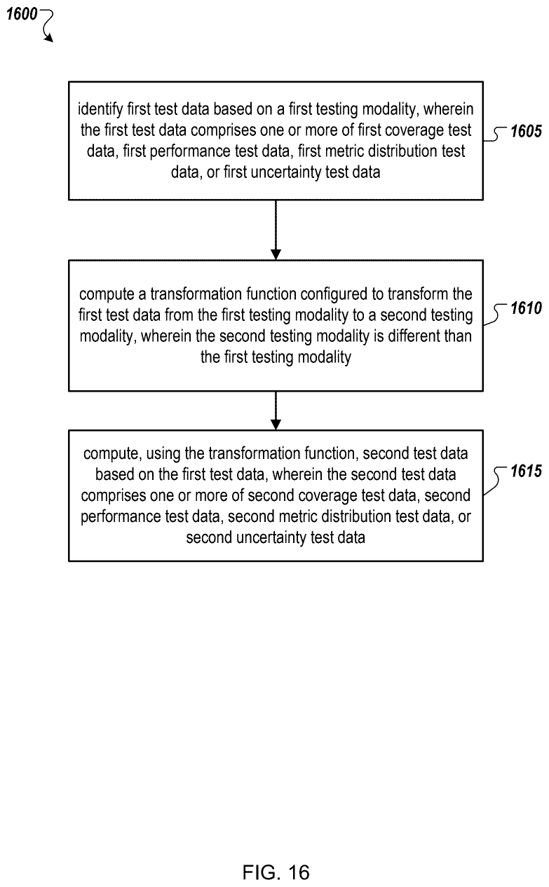

FIG. 16 illustrates a process flow of an example method 1600 that may be used for vehicle testing, simulation, or validation, in accordance with at least one example described in the present disclosure. The method 1600 may be arranged in accordance with at least one example described in the present disclosure.

The method 1600 may be performed by processing logic that may include hardware (circuitry, dedicated logic, etc.), software (such as is run on a computer system or a dedicated machine), or a combination of both, which processing logic may be included in the processing device 1702 of FIG. 17, or another device, combination of devices, or systems.

The method 1600 may begin at block 1605 where the processing logic may identify first test data based on a first testing modality, where the first test data includes one or more of first coverage test data, first performance test data, first metric distribution test data, or first uncertainty test data.

At block 1610, the processing logic may compute a transformation function configured to transform the first test data from the first testing modality to a second testing modality, where the second testing modality is different from the first testing modality.

At block 1615, the processing logic may compute, using the transformation function, second test data based on the first test data, where the second test data includes one or more of second coverage test data, second performance test data, second metric distribution test data, or second uncertainty test data.

The processor may be further configured to execute instructions to cause the device to perform one or more of: compute an information loss metric based on one or more of the first test data or the second test data, where the information loss metric is the amount of information loss for the second test data compared to the first test data; compute a risk metric based on one or more of the first test data or the second test data, where the risk metric is the amount of risk for the second test data compared to the risk for the first test data; compute an uncertainty metric based on one or more of the first test data or the second test data, where the uncertainty metric is the amount of uncertainty for the second test data compared to the uncertainty for the first test data; compute a transformation testing time to compute the second test data, using the transformation function, based on the first test data; compute a non-transformation testing time to compute the second test data without using the transformation function and the first test data; or compute a test time savings based on the difference between the transformation testing time and the non-transformation testing time. The first testing modality may be one or more of: software in the loop (SIL), hardware in the loop (HIL), tracking testing. The second testing modality may be one or more of: software in the loop (SIL), hardware in the loop (HIL), tracking testing

Modifications, additions, or omissions may be made to the method 1600 without departing from the scope of the present disclosure. For example, in some examples, the method 1600 may include any number of other components that may not be explicitly illustrated or described.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

In some examples, a vehicle (e.g., an AV) simulation, testing, and validation systems may include an environmental representation-creation module that may include code and routines configured to enable a computing device to perform one or more operations with respect to generating a 3-D environmental representation, preparing and generating scenarios, simulating the scenarios, and validating and/or evaluating the simulations of the scenarios, etc. Additionally or alternatively, the environmental representation-creation module may be implemented using hardware including a processor, a microprocessor (e.g., to perform or control performance of one or more operations), a field-programmable gate array (FPGA), or an application-specific integrated circuit (ASIC). In some other instances, the environmental representation-creation module may be implemented using a combination of hardware and software. In the present disclosure, operations described as being performed by the environmental representation-creation module may include operations that the environmental representation-creation module may direct a corresponding system to perform.

In some examples, the environmental representation-creation module may be configured to generate the 3-D environmental representation. The environmental representation-creation module may generate the 3-D environmental representation according to any suitable 3-D modeling technique. In some examples, the environmental representation-creation module may use map data as input data in the generation of the 3-D environmental representation. For example, the 3-D environment of the 3-D environmental representation may represent the geographic area represented by the map data.

In some examples, the 3-D environmental representation may include a 3-D model of one or more objects in the geographic area as described by map data. For example, the 3-D environmental representation may include a complete 3-D model of the simulated driving environment.

The vehicle (e.g., an AV) simulation, testing, and validation system may include machine learning circuitry and/or software to identify failure cases more efficiently and proactively. The vehicle (e.g., an AV) simulation, testing, and validation system may include circuitry and/or software for pruning, including parameter-based pruning. The vehicle (e.g., an AV) simulation, testing, and validation system may include circuitry and/or software to implement runtime constraints on a scenario, simulation, or within a 3-D environmental representation.

FIG. 17 illustrates a diagrammatic representation of a machine in the example form of a computing device 1700 within which a set of instructions, for causing the machine to perform any one or more of the methods discussed herein, may be executed. The computing device 1700 may include a rackmount server, a router computer, a server computer, a mainframe computer, a laptop computer, a tablet computer, a desktop computer, or any computing device with at least one processor, etc., within which a set of instructions, for causing the machine to perform any one or more of the methods discussed herein, may be executed. In alternative examples, the machine may be connected (e.g., networked) to other machines in a local area network (LAN), an intranet, an extranet, or the Internet. The machine may operate in the capacity of a server machine in client-server network environment. Further, while only a single machine is illustrated, the term “machine” may also include any collection of machines that individually or jointly execute a set (or multiple sets) of instructions to perform any one or more of the methods discussed herein.

The example computing device 1700 includes a processing device (e.g., a processor) 1702, a main memory 1704 (e.g., read-only memory (ROM), flash memory, dynamic random access memory (DRAM) such as synchronous DRAM (SDRAM)), a static memory 1706 (e.g., flash memory, static random access memory (SRAM)) and a data storage device 1716, which communicate with each other via a bus 1708.

Processing device 1702 represents one or more general-purpose processing devices such as a microprocessor, central processing unit, or the like. More particularly, the processing device 1702 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 1702 may also include one or more special-purpose processing devices such as an application specific integrated circuit (ASIC), a field programmable gate array (FPGA), a digital signal processor (DSP), network processor, or the like. The processing device 1702 is configured to execute instructions 1726 for performing the operations and steps discussed herein.

The computing device 1700 may further include a network interface device 1722 which may communicate with a network 1718. The computing device 1700 also may include a display device 1710 (e.g., a liquid crystal display (LCD) or a cathode ray tube (CRT)), an alphanumeric input device 1712 (e.g., a keyboard), a cursor control device 1714 (e.g., a mouse) and a signal generation device 1720 (e.g., a speaker). In at least one example, the display device 1710, the alphanumeric input device 1712, and the cursor control device 1714 may be combined into a single component or device (e.g., an LCD touch screen).

The data storage device 1716 may include a computer-readable storage medium 1724 on which is stored one or more sets of instructions 1726 embodying any one or more of the methods or functions described herein. The instructions 1726 may also reside, completely or at least partially, within the main memory 1704 and/or within the processing device 1702 during execution thereof by the computing device 1700, the main memory 1704 and the processing device 1702 also constituting computer-readable media. The instructions may further be transmitted or received over a network 1718 via the network interface device 1722.

While the computer-readable storage medium 1724 is shown in an example to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

### EXAMPLES

The following provide examples of the present disclosure.

### Example 1: Lane Support Using an Open SCENARIO

In this example, a target vehicle and an ego vehicle are described with respect to a route. The ego vehicle drives along the route and is initially in the same lane as the target vehicle. The target vehicle is speeding towards the ego vehicle and has about 0.1 meters of distance to the lane marking on the right. The ego vehicle has about 100 meters of distance between itself and the target vehicle at the start of the scenario and has about a distance of 0.5 to the lane marking on the right. The ego vehicle transitions to a different lane during the scenario. The ego vehicle transitions back to the same lane as the target vehicle at the end of the scenario.

An example of the OpenSCENARIO 2.0 scenario format is provided in Table I.

TABLE I
Go-Behind Lane Support

Import osc.standard
Scenario go_behind:

| | |
|---|---|
| target: vehicle | #target vehicle |
| ego: vehicle | #ego vehicle |

routeForward: route with:

| | |
|---|---|
| keep (it.min_lanes == 2) | #Route 2+ lanes |

```
  do parallel:
    ego.drive(duration: 15s) with:
      along(route: routeForward)
      lane(same_as: target, at: start)
      lane(same_as: target, at: end)
      lateral(distance: 0.5m, measure by: right_to_right, at: start)
      position(distance 100.0m, front_of: target, at: start)
      position(distance 20.0m, behind_of: target, at: end)
  #The ego vehicle begins the scenario in the same lane as the target
  vehicle
  #at the start, transitions to a different lane, falls behind the target
  vehicle,
  #and then transitions back to the same lane over the course of 15s.
    target.drive( ) with:
      along(route: routeFoward)
      speed(speed: 150 kph)
      lateral(distance: 0.1m, measure by: right_to_right, at: start)
    #The target vehicle follows the route in the same lane as the ego
    #vehicle at the start at a speed of 150 kph, and close to the lane
    #marking on the right.
```

### Example 2: OpenSCENARIO to Internal Parameter Format Conversion

The scenario description language, OpenSCENARIO, may be converted to an internal parameter format.

The OpenSCENARIO code provided in Table I includes: (i) axes (e.g., vehicles, routes, lanes, lateral, position, speed, and the like), (ii) relationships (e.g., target vehicle and ego vehicle in same lanes), and (iii) constraints (e.g., at least 2 lanes). The OpenSCENARIO code may be mapped to the internal parameter format by identifying the OpenSCENARIO axes, relationships, and constraints and converting those axes, relationships, and constraints into an internal parameter format (e.g., an intermediate YAML format).

### Example 3: Testing in Parallel Using Asynchronous Information

Two different scenarios in an OpenSCENARIO language may be converted to an internal parameter format. Both scenarios may be tested in the same batch as a first test and a second test. The first test based on the first scenario may complete testing before the second test based on the scenario completes testing. The results of the first test based on the first scenario may be used in a third test based on the second scenario.

The first scenario is provided in Table I and the second scenario is provided in Table II.

TABLE II
Stay-Ahead Lane Support

Import osc.standard
Scenario stay_ahead:

| | |
|---|---|
| target: vehicle | #target vehicle |
| ego: vehicle | #ego vehicle |

routeForward: route with:

| | |
|---|---|
| keep (it.min_lanes == 2) | #Route 2+ lanes |

```
  do parallel:
    ego.drive(duration: 25s) with:
      along(route: routeForward)
      lane(same_as: target, at: start)
      lane(same_as: target, at: end)
      lateral(distance: 0.5m, measure by: right_to_right, at: start)
      position(distance 100.0m, front_of: target, at: start)
      position(distance 20.0m, ahead_of: target, at: end)
      speed(speed: 100 kph, at: start)
      speed(speed: 130 kph, at: end)
  #The ego vehicle begins the scenario in the same lane as the target
  vehicle
  #at the start, does not change lanes and speeds up to but stays 20 kph
  #below the speed of the target vehicle at the end. The scenarios takes
  25s.
    target.drive( ) with:
      along(route: routeFoward)
      speed(speed: 150 kph, at: start)
      lateral(distance: 0.1m, measure by: right_to_right, at: start)
    #The target vehicle follows the route in the same lane as the ego
    #vehicle at the start at a speed of 150 kph, and close to the lane
    #marking on the right. The target vehicle starts at a speed of 150
    #kph.
```

In the second scenario, the ego vehicle does not change lanes in response to the target vehicle speeding behind it in the same lane. The ego vehicle speeds up from 100 kph to 130 kph. The target vehicle starts the scenario at a speed of 150 kph. This scenario may be used to test an automated vehicle's response to an approaching car.

The first test results from the first scenario may indicate that the ego vehicle does not change lanes and allows the ego vehicle to crash into it from behind. These first test results, when completed before the completion of the second test results, may be used to adjust the third test based on the second scenario. Knowing that the ego vehicle is unable to change lanes and the target car crashes into the ego vehicle may be used to modify the third scenario by, e.g., decreasing the speed of the target vehicle to test whether the ego vehicle will be able to sense the target vehicle and avoid crashing.

### Example 4: Parametric Metrics Using an Internal Parameter Format and Asynchronous Information

The scenarios set forth in Tables I (“Go-Behind”) and II (“Stay-Ahead) may be used to compute parametric metrics. Converting the scenarios to the internal parameter format (e.g., an intermediate YAML format) may enhance the performance and information gain received for the parametric metrics (e.g., one or more of a parametric performance metric or a parametric coverage metric).

The scenarios represented using OpenSCENARIO may be converted to an internal parameter format to facilitate the conversion of the scenarios to different testing modalities (e.g., SIL, HIL, track) and to convert the test results from the different testing modalities back into the internal parameter format. The metrics from different testing modalities may be compared using the same language. Thus, the parametric coverage metric and the parametric performance metrics may be computed with greater accuracy and precision compared to computations based on differing languages.

For the scenarios described in Go-Behind and Stay-Ahead, one performance metric may be the frequency with which the ego vehicle crashes as a result of: (i) changing lanes to allow the target vehicle to pass, or (ii) staying in the same lane and increasing speed. The coverage metric may be computed based on the number of different situations (e.g., different weather, car speeds, road types, or the like) related to these scenarios in Go-Behind and Stay-Ahead that are tested based on the test data from the scenarios in Go-Behind and Stay-Ahead.

Converting the OpenSCENARIO format to the internal parameter format (e.g., the intermediate YAML format) may facilitate combining data from the OpenSCENARIO format with data from a different scenario language (i.e., not an OpenSCENARIO language) and computing metrics based on the combined data. A different scenario language may gather data related to weather conditions and road types for an ego vehicle and a target vehicle in a scenario that is different (e.g., Combined-Lane-Change scenario in which the ego vehicle and the target vehicle switch lanes around the same time while traveling within a selected distance from each other). The data from this scenario may be converted to the internal parameter format (e.g., the intermediate YAML format) and combined with the data from the scenarios described in Go-Behind and Stay-Ahead. The sum of the coverage metric as provided by Go-Behind and Stay-Ahead and the coverage metric as provided by the Combined-Lane-Change scenario may not be the same as the coverage metric when the scenarios described in Tables I and II are combined with the Combined-Lane-Change before computing the coverage metric.

Asynchronous test results may be used to increase the information gain and reduce the computational complexity and testing time. For a situation in which Go-Behind scenario and the Combined-Lane-Change scenarios complete testing before the Stay-Ahead scenario completes testing, the Go-Behind and Combined-Lane-Change scenarios may be converted to the internal parameter format (e.g., the intermediate YAML format) before the performance and/or coverage metrics are computed. The resulting performance and/or coverage metrics may be used to select specific algorithms to apply to a subsequent testing batch before the test data from the Stay-Ahead scenario has completed.

### Example 5: Metrics Using an Internal Parameter Format and Asynchronous Information

The Go-Behind, Stay-Ahead, and Combined-Lane-Change scenarios may be used with a metric. The metric may be computed using one or more of a confidence level, a confidence interval, a normalized format, or a sample density. For example, the Go-Behind scenario may have a crash rate of 2%, the Stay-Ahead scenario may have a crash rate of 3%, and the Combined-Lane-Change scenario may have a crash rate of 5%. Confidence levels and intervals may be computed for these scenarios. The Go-Behind scenario crash rate of 2% may have a confidence interval of 2.5% to 3.5% with a confidence level of 95%. The Stay-Ahead scenario crash rate of 3% may have a confidence interval of 3.5% to 4.5% with a confidence level of 97%. The Combined-Lane-Change scenario crash rate of 5% may have a confidence interval of 3% to 8% with a confidence level of 85%.

A normalized format may be computed by combining the three different scenarios using an internal parameter format and normalizing the data so that the area under the curve is equal to about 1. The sample density may be computed based on the sample densities for each of the scenarios.

The metric may be combined into a single metric (e.g., a unified metric) that combines the coverage metric and the performance metric. The single metric may be used to determine what to test. For example, a coverage metric based on the Go-Behind, Stay-Ahead, and Combined-Lane-Change scenarios may indicate that coverage is not provided for scenarios in which two vehicles change lanes at the same time into the same lane traveling at a speed of 300 kph during a snowstorm, but the single metric may compute that the scenario is not to be tested because the performance (e.g., a crash) is known.

### Example 6: Transformation Functions

First test data computed using a first testing modality may be transformed to second test data for a second testing modality. For example, the first test data may be SIL test data, and second test data may be HIL data. A transformation function may be determined between the first testing modality and the second testing modality using a suitable machine learning technique such as supervised machine learning (e.g., regression) using training data for the first and second testing modalities. An objective function may be optimized to generate one or more functions used to transform between testing modalities.

For the Go-Behind, Stay-Ahead, and Combined-Lane-Change scenarios, the testing modality may include SIL testing data. The SIL testing data may be converted to HIL testing data using a transformation function. Transforming the SIL testing data to the HIL testing data using a transformation function may facilitate a reduction in testing time.

In some examples, the different components, modules, engines, and services described herein may be implemented as objects or processes that execute on a computing system (e.g., as separate threads). While some of the systems and methods described herein are generally described as being implemented in software (stored on and/or executed by hardware), specific hardware implementations or a combination of software and specific hardware implementations are also possible and contemplated.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although examples of the present disclosure have been described in detail, it should be understood that the various changes, substitutions, and alterations could be made hereto without departing from the spirit and scope of the present disclosure.

What is claimed is:

1. A device for vehicle testing, comprising:
a memory; and
a processor operatively coupled to the memory, the processor being configured to execute instructions to cause the device to:
test a first test sample batch comprising a plurality of first test samples to output a plurality of first test sample results;
identify one or more asynchronous test sample results of the plurality of first test samples before the first test sample batch is complete;
compute a parametric metric based on the one or more asynchronous test sample results, wherein the parametric metric includes one or more of a parametric performance metric or a parametric coverage metric; and
adjust a second test sample batch based on the parametric metric.

2. The device of claim 1, wherein the processor is further configured to execute instructions to cause the device to:
determine the one or more asynchronous test sample results based on a parametric metric that includes one or more of a parametric performance metric or a parametric coverage metric.

3. The device of claim 1, wherein the processor is further configured to execute instructions to cause the device to:
determine the one or more asynchronous test sample results based on real world data.

4. The device of claim 1, wherein the processor is further configured to execute instructions to cause the device to:
terminate the first sample batch based on the parametric metric.

5. The device of claim 1, wherein the processor is further configured to execute instructions to cause the device to:
convert the plurality of first test samples from an internal parameter format to a testing modality format; and
convert the one or more asynchronous test sample results to the internal parameter format from the testing modality format.

6. The device of claim 1, wherein the processor is further configured to execute instructions to cause the device to:
adjust the second test sample batch based on test adjustment configuration parameters including one or more of: a learning rate decay parameter, a sample size parameter, a hyper parameter, or an algorithm selection parameter.

7. The device of claim 1, wherein the plurality of first test sample results are generated using a plurality of different testing modalities.

8. A device for vehicle testing, comprising:
a memory; and
a processor operatively coupled to the memory, the processor being configured to execute instructions to cause the device to:
identify one or more asynchronous test sample results of a plurality of first test samples before a first test sample batch has completed testing;
compute a parametric metric, wherein the parametric metric is based on one or more of a parametric performance metric or a parametric coverage metric;
select a set of algorithms based on the parametric metric; and
apply an algorithm of the set of algorithms to a second test sample batch before the first test sample batch has completed testing.

9. The device of claim 8, wherein the parametric metric is based on a use case.

10. The device of claim 8, wherein the parametric metric is computed using one or more of an objective function or real world data.

11. The device of claim 8, wherein the processor is further configured to execute instructions to cause the device to:
compute a parametric metric including one or more of: a confidence level, a confidence interval, a normalized metric, or sample density.

12. The device of claim 8, wherein the processor is further configured to execute instructions to cause the device to:
select a set of axes based on the parametric metric; or
display a result based on the set of axes on a display device; or
select a subset of the set of axes; or
display a subset of the result based on the subset of the set of axes on the display device.

13. The device of claim 8, wherein the processor is further configured to execute instructions to cause the device to:
retrieve one or more axes values for one or more testing modalities; and
compute one or more axes-specific metrics based on the one or more axes values.

14. The device of claim 8, wherein the processor is further configured to execute instructions to cause the device to:
generate a test configuration object based on one or more axes-specific metrics, wherein the one or more axes-specific metrics are based on one or more axes value selected based on the parametric metric.

15. A computer-readable storage medium including computer executable instructions that, when executed by one or more processors, cause a vehicle tester to:
test a first test sample batch in a testing modality format, wherein the first sample batch comprises a plurality of first test samples to output a plurality of first test sample results;
identify one or more asynchronous test sample results of the plurality of first test samples before the first test sample batch is complete;
convert the one or more asynchronous test sample results to an internal parameter format from the testing modality format; and
adjust a second test sample batch based on the one or more asynchronous test sample results.

16. The computer readable medium of claim 15, wherein the instructions, when executed by the one or more processors, further cause the vehicle tester to:
format the second test sample batch into a testing modality format for the testing modality; and
send the second test sample batch to the testing modality,
wherein the testing modality includes one or more of a software in the loop (SIL) simulator plugin interface, a hardware in the loop (HIL) simulator plugin interface, or a track testing plugin interface.

17. The computer readable medium of claim 15, wherein the instructions, when executed by the one or more processors, further cause the vehicle tester to:
convert, at an internal parameter format converter plugin, axes data in a time-based metrics signal format into the internal parameter format data; and
write the axes data to a database.

18. The computer readable medium of claim 15, wherein the instructions, when executed by the one or more processors, further cause the vehicle tester to:
compute a parametric metric, wherein the parametric metric is based on one or more of a parametric performance metric or a parametric coverage metric, wherein the parametric metric is based on a use case.

19. The computer readable medium of claim 15, wherein the instructions, when executed by the one or more processors, further cause the vehicle tester to:
retrieve one or more axes values for the testing modality; and
compute one or more axes-specific metrics based on the one or more axes values.

20. The computer readable medium of claim 15, wherein the instructions, when executed by the one or more processors, further cause the vehicle tester to:
generate the second test sample batch based on one or more axes-specific metrics, wherein the one or more axes-specific metrics are based on one or more axes value selected based on a parametric metric.
